(19) United States
(12) Patent Application Publication
(10) Pub. No.: US 2026/0123046 A1
(43) Pub. Date: Apr. 30, 2026

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Bongkwan BAEK, Suwon-si (KR); Junchae LEE, Suwon-si (KR); Jongmin BAEK, Suwon-si (KR); Kyu-Hee HAN, Suwon-si (KR)

(73) Assignee: SAMSUNG ELECTRONICS CO., LTD., Suwon-si (KR)

(21) Appl. No.: 19/222,246

(22) Filed: May 29, 2025

(30) Foreign Application Priority Data
Oct. 30, 2024 (KR) 10-2024-0151229

(51) Int. Cl. H10D 84/90; H10D 89/10

(52) U.S. Cl. CPC H10D 84/964; H10D 84/953; H10D 89/10

(57) ABSTRACT

A semiconductor device includes a substrate including a first active pattern and a second active pattern that are spaced apart from each other in a first direction that is parallel to a top surface of the substrate, a first source/drain pattern on the first active pattern, a second source/drain pattern on the second active pattern, a first active contact on the first source/drain pattern, a second active contact on the second source/drain pattern, and a cutting pattern between the first active contact and the second active contact, where the cutting pattern may include a first cutting pattern between the first active contact and the second active contact, the first cutting pattern extending toward the substrate, and a second cutting pattern on at least one lateral surface of the first cutting pattern and a bottom surface of the first cutting pattern, the second cutting pattern exposing at least a portion of the at least one lateral surface of the first cutting pattern.

### CROSS-REFERENCE TO RELATED APPLICATION

This application is based on and claims priority to Korean Patent Application No. 10-2024-0151229, filed on Oct. 30, 2024 in the Korean Intellectual Property Office, the disclosure of which is incorporated by reference herein in its entirety.

### BACKGROUND

The present disclosure relates to a semiconductor device and a method of fabricating the same, and more particularly, to a semiconductor device including a field effect transistor and a method of fabricating the same.

A semiconductor device may include an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various studies have been conducted to develop methods of fabricating semiconductor devices having superior performances while overcoming limitations caused by high integration of the semiconductor devices.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device with increased electrical properties.

One or more example embodiments provide a method of fabricating a semiconductor device with increased reliability.

According to an aspect of an example embodiment, a semiconductor device may include a substrate including a first active pattern and a second active pattern that are spaced apart from each other in a first direction that is parallel to a top surface of the substrate, a first source/drain pattern on the first active pattern, a second source/drain pattern on the second active pattern, a first active contact on the first source/drain pattern, a second active contact on the second source/drain pattern, and a cutting pattern between the first active contact and the second active contact, where the cutting pattern may include a first cutting pattern between the first active contact and the second active contact, the first cutting pattern extending toward the substrate, and a second cutting pattern on at least one lateral surface of the first cutting pattern and a bottom surface of the first cutting pattern, the second cutting pattern exposing at least a portion of the at least one lateral surface of the first cutting pattern.

According to an aspect of an example embodiment, a semiconductor device may include a substrate including a first active pattern and a second active pattern, a first source/drain pattern on the first active pattern, a second source/drain pattern on the second active pattern, a first active contact on the first source/drain pattern, a second active contact on the second source/drain pattern, and a cutting pattern between the first active contact and the second active contact, where the cutting pattern may include a first cutting pattern between the first active contact and the second active contact, the first cutting pattern extending toward the substrate, and a second cutting pattern on at least one lateral surface of the first cutting pattern and a bottom surface of the first cutting pattern, where the first cutting pattern may include a first lateral surface that faces the first active contact, and a second lateral surface across from the first lateral surface, where the second cutting pattern may include a first cutting portion on the first lateral surface of the first cutting pattern, the first cutting portion having a first thickness, and a second cutting portion on the second lateral surface of the first cutting pattern, the second cutting portion having a second thickness, and where the first thickness is different from the second thickness.

According to an aspect of an example embodiment, a semiconductor device may include a substrate including a first active pattern and a second active pattern, a device isolation layer between the first active pattern and the second active pattern, a first source/drain pattern on the first active pattern, a first channel pattern on the first active pattern, a second source/drain pattern on the second active pattern, a second channel pattern on the second active pattern, a gate electrode across the first channel pattern and the second channel pattern, a first active contact on the first source/drain pattern, a second active contact on the second source/drain pattern, and a cutting pattern between the first active contact and the second active contact, where the cutting pattern may include a first cutting pattern between the first active contact and the second active contact, the first cutting pattern extending toward the substrate, and a second cutting pattern on at least one lateral surface of the first cutting pattern and a bottom surface of the first cutting pattern, the second cutting pattern exposing at least a portion of the at least one lateral surface of the first cutting pattern.

### BRIEF DESCRIPTION OF DRAWINGS

The above and other aspects, features, and advantages of certain example embodiments of the present disclosure will be more apparent from the following description taken in conjunction with the accompanying drawings, in which:

FIGS. 1 to 3 are diagrams illustrating logic cells of a semiconductor device according to one or more embodiments;

FIG. 4 is a plan view illustrating a semiconductor device according to one or more embodiments;

FIGS. 5A to 5E are cross-sectional views illustrating a semiconductor device according to one or more embodiments;

FIG. 5F is an enlarged view illustrating section M of FIG. 4 according to one or more embodiments;

FIG. 5G is an enlarged view illustrating section N of FIG. 5C according to one or more embodiments;

FIG. 5H is an enlarged view illustrating section O of FIG. 7D according to one or more embodiments;

FIGS. 6A to 17H are diagrams illustrating a method of fabricating a semiconductor device according to one or more embodiments;

FIG. 18 is a plan view illustrating a semiconductor device according to one or more embodiments;

FIGS. 19A to 19E are cross-sectional views illustrating a semiconductor device according to one or more embodiments;

FIG. 19F is an enlarged view illustrating section M of FIG. 18 according to one or more embodiments;

FIG. 19G is an enlarged view illustrating section N of FIG. 19C according to one or more embodiments;

FIG. 19H is an enlarged view illustrating section O of FIG. 19D according to one or more embodiments; and

FIGS. 20 to 21H are diagrams illustrating a method of fabricating a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

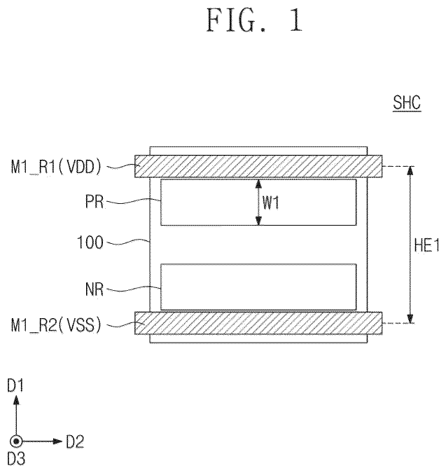

FIGS. 1 to 3 are diagrams illustrating logic cells of a semiconductor device according to one or more embodiments.

Referring to FIG. 1, a single height cell SHC may be provided. For example, a first power line M1_R1 and a second power line M1_R2 may be provided on a substrate 100. The first power line M1_R1 may be a path for providing a drain voltage VDD, for example, a power voltage. The second power line M1_R2 may be a path for providing a source voltage VSS, for example, a ground voltage.

The single height cell SHC may be defined between the first power line M1_R1 and the second power line M1_R2. The single height cell SHC may include one p-type metal-oxide-semiconductor (MOS) field effect transistor (FET) (MOSFET) (PMOSFET) region PR and one n-type MOSFET (NMOSFET) region NR. For example, the single height cell SHC may have a complementary metal oxide semiconductor (CMOS) structure provided between the first power line M1_R1 and the second power line M1_R2.

Each of the PMOSFET and NMOSFET regions PR and NR may have a first width W1 in a first direction D1. A first height HE1 may be defined to refer to a length in the first direction D1 of the single height cell SHC. The first height HE1 may be substantially the same as a distance (e.g., pitch) between the first power line M1_R1 and the second power line M1_R2.

The single height cell SHC may constitute one logic cell. In this description, the logic cell may refer to a logic device, such as AND, OR, XOR, XNOR, and inverter, that performs a specific function. For example, the logic cell may include transistors for constituting a logic device, and may also include wiring lines that connect the transistors to each other.

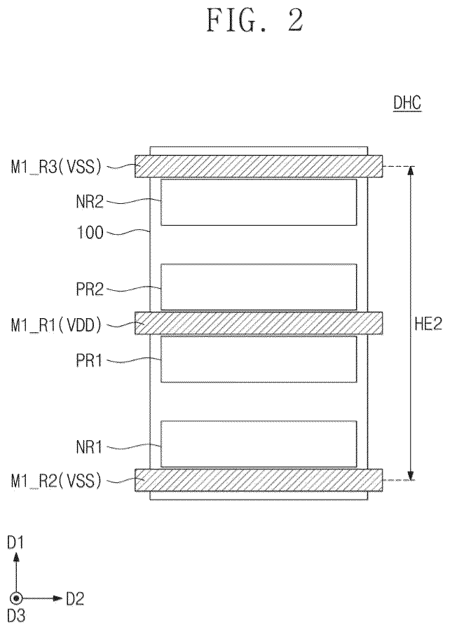

Referring to FIG. 2, a double height cell DHC may be provided. For example, a substrate 100 may be provided thereon with a first power line M1_R1, a second power line M1_R2, and a third power line M1_R3. The first power line M1_R1 may be disposed between the second power line M1_R2 and the third power line M1_R3. The third power line M1_R3 may be a path for providing a source voltage VSS.

The double height cell DHC may be defined between the second power line M1_R2 and the third power line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the second power line M1_R2. The second NMOSFET region NR2 may be adjacent to the third power line M1_R3. The first and second PMOSFET regions PR1 and PR2 may be adjacent to the first power line M1_R1. In a plan view, the first power line M1_R1 may be disposed between the first and second PMOSFET regions PR1 and PR2.

A second height HE2 may be defined to refer to a length in the first direction D1 of the double height cell DHC. The second height HE2 may be about twice the first height HE1 of FIG. 1. The first and second PMOSFET regions PR1 and PR2 of the double height cell DHC may collectively operate as a single PMOSFET region.

Therefore, the double height cell DHC may have a PMOS transistor whose channel size is greater than that of a PMOS transistor included in the single height cell SHC discussed above in FIG. 1. For example, the channel size of the PMOS transistor included in the double height cell DHC may be about twice that of the PMOS transistor included in the single height cell SHC. The double height cell DHC may operate at a higher speed than that of the single height cell SHC. The double height cell DHC shown in FIG. 2 may be defined as a multi-height cell. The multi-height cell may include a triple height cell whose cell height is about three times that of the single height cell SHC.

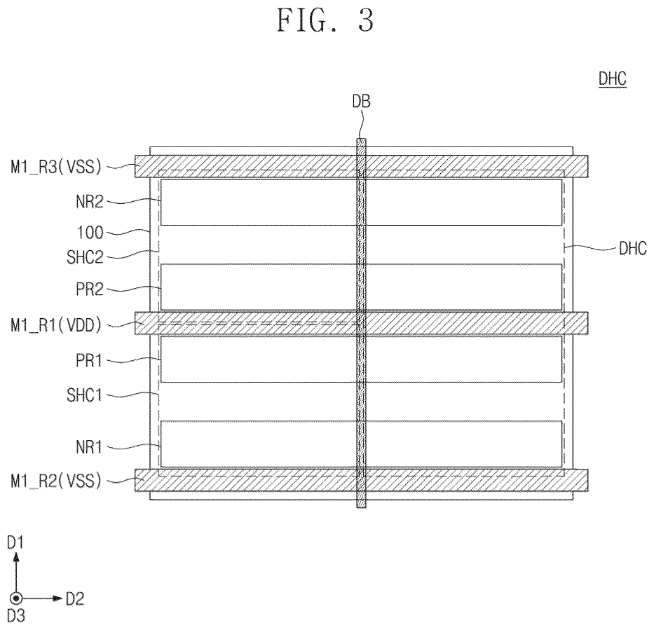

Referring to FIG. 3, a substrate 100 may be provided thereon with a first single height cell SHC1, a second single height cell SHC2, and a double height cell DHC that are two-dimensionally disposed. The first single height cell SHC1 may be disposed between a first power line M1_R1 and a second power line M1_R2. The second single height cell SHC2 may be disposed between the first power line M1_R1 and a third power line M1_R3. The second single height cell SHC2 may be adjacent in a first direction D1 to the first single height cell SHC1.

The double height cell DHC may be disposed between the second power line M1_R2 and the third power line M1_R3. The double height cell DHC may be adjacent in a second direction D2 to the first and second single height cells SHC1 and SHC2.

A separation structure DB may be provided between the first single height cell SHC1 and the double height cell DHC and between the second single height cell SHC2 and the double height cell DHC. The separation structure DB may electrically separate an active region of the double height cell DHC from an active region of each of the first and second single height cells SHC1 and SHC2.

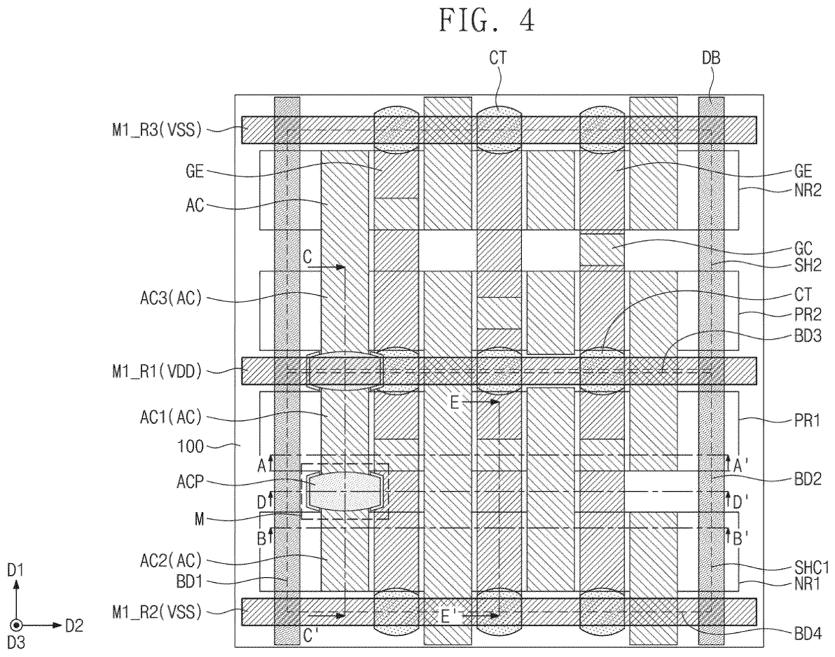

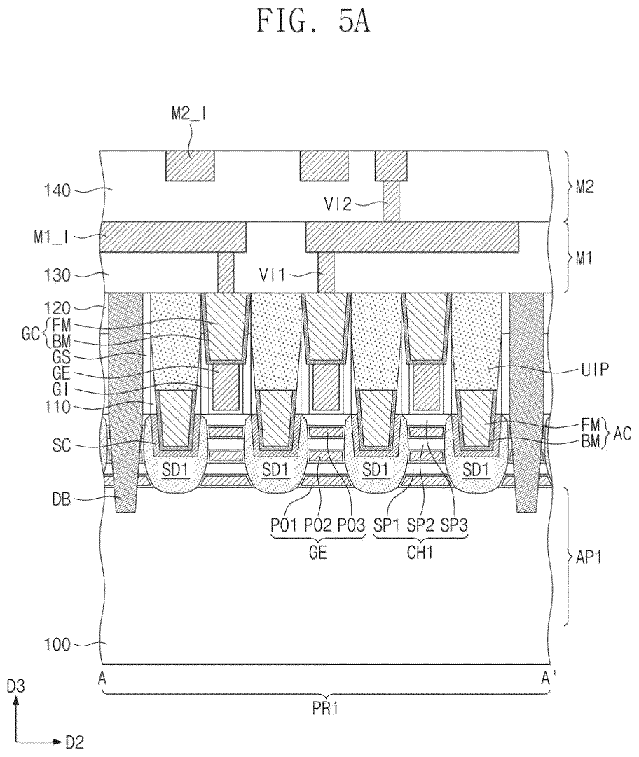

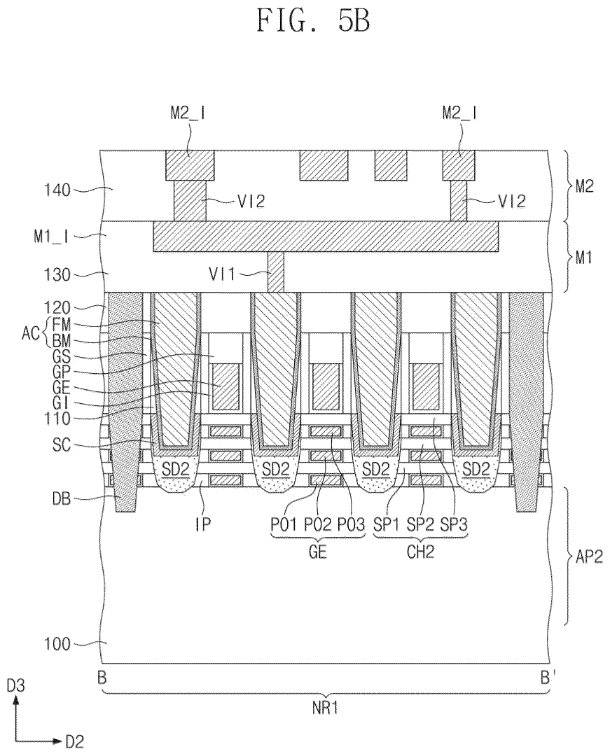

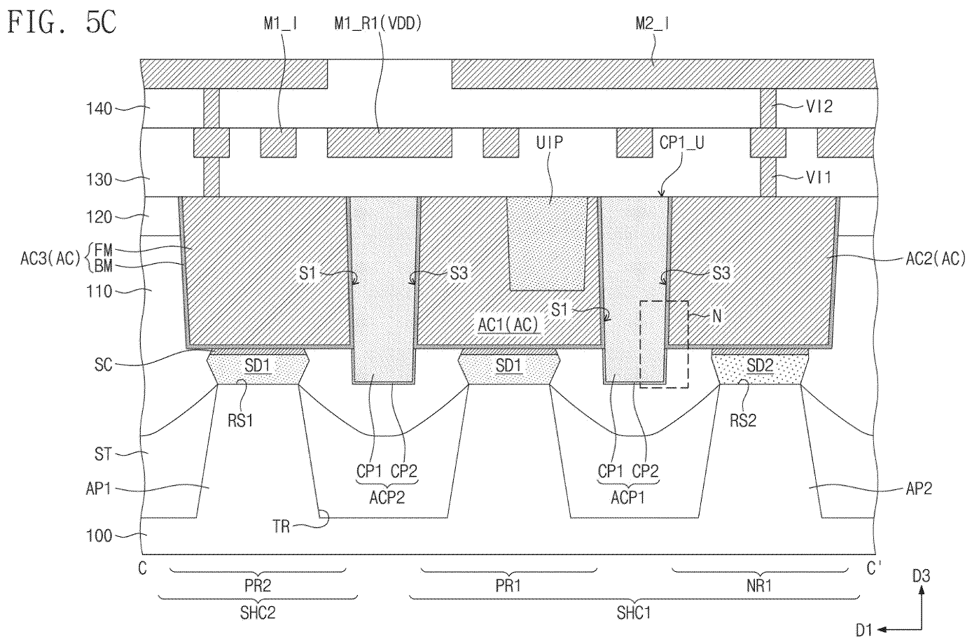

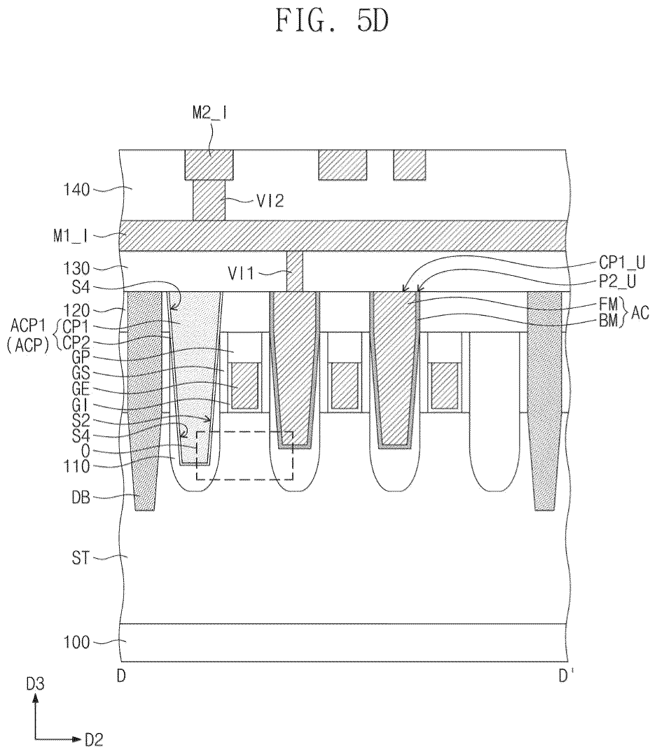

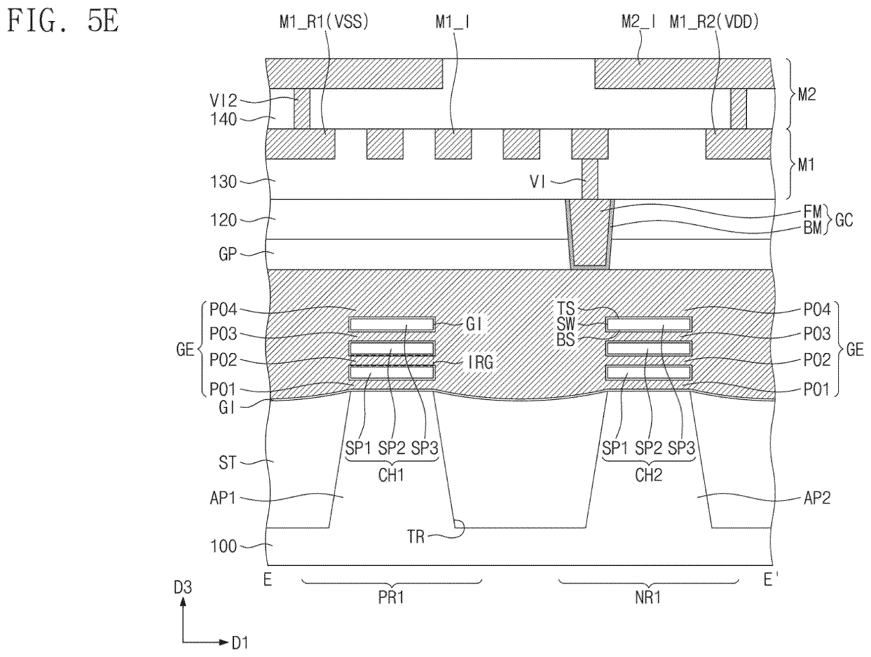

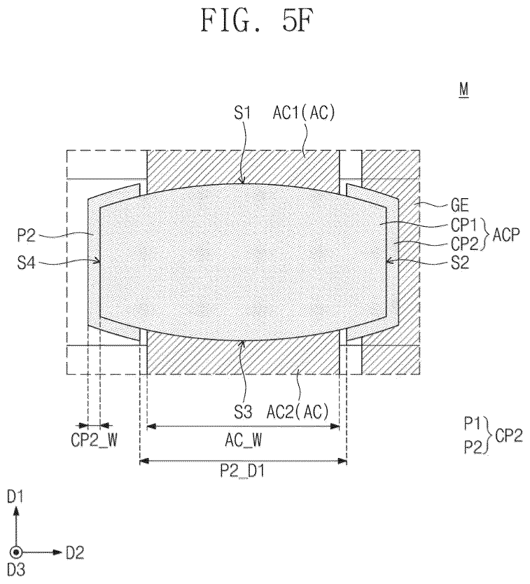

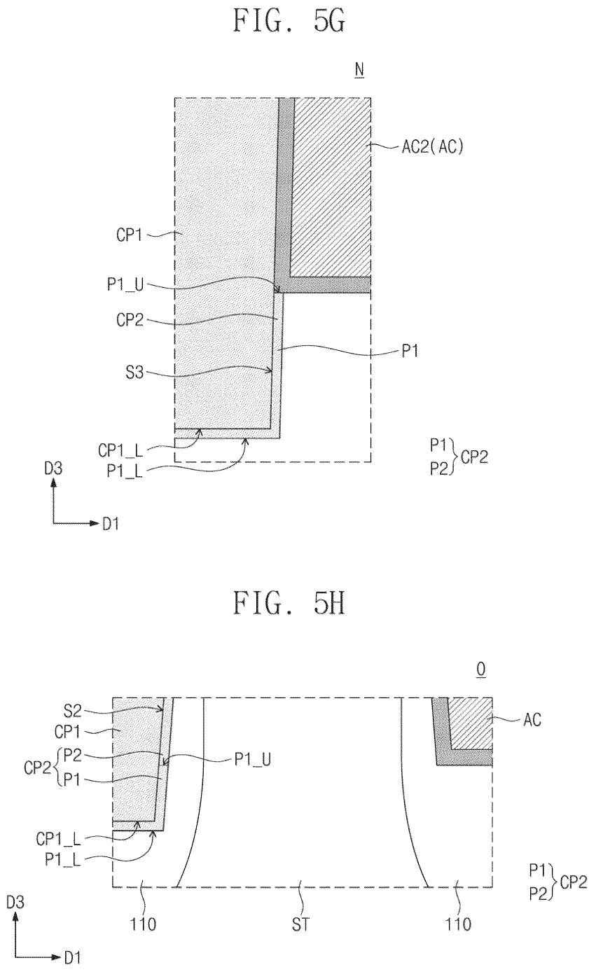

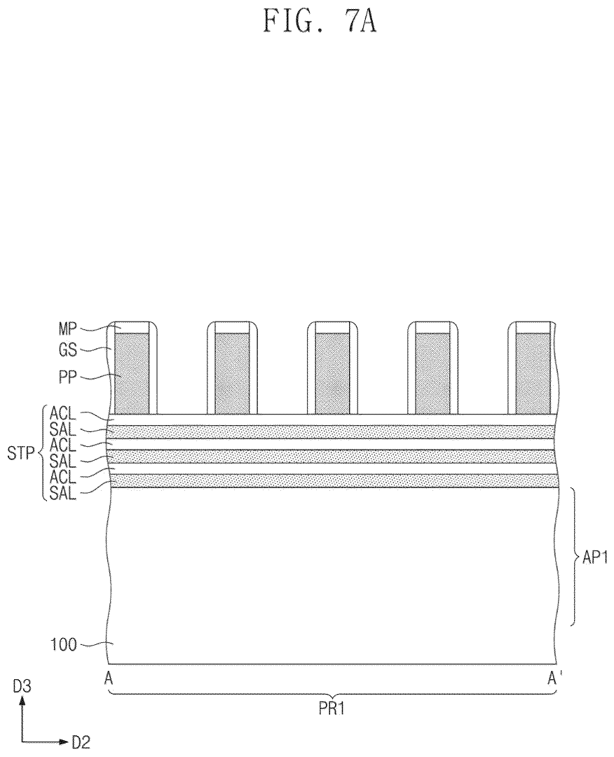

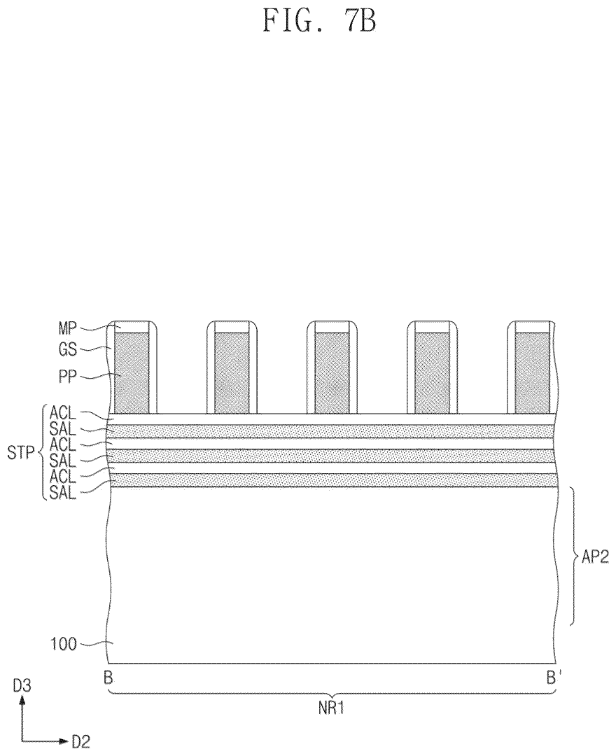

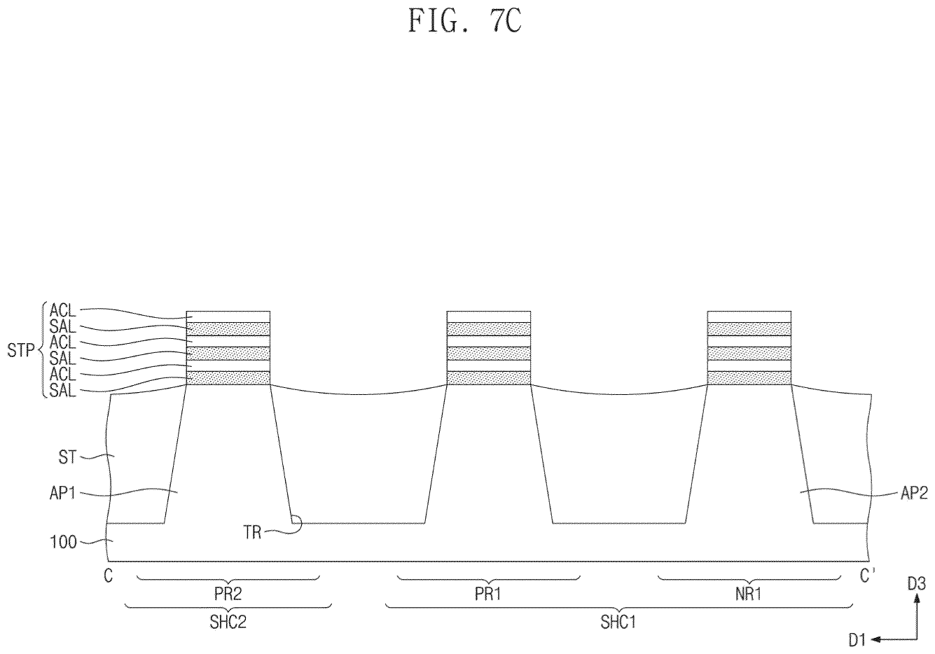

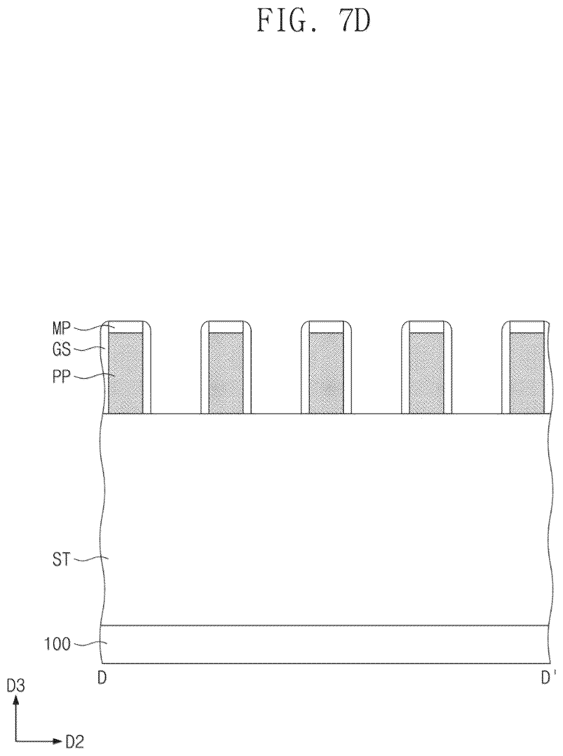

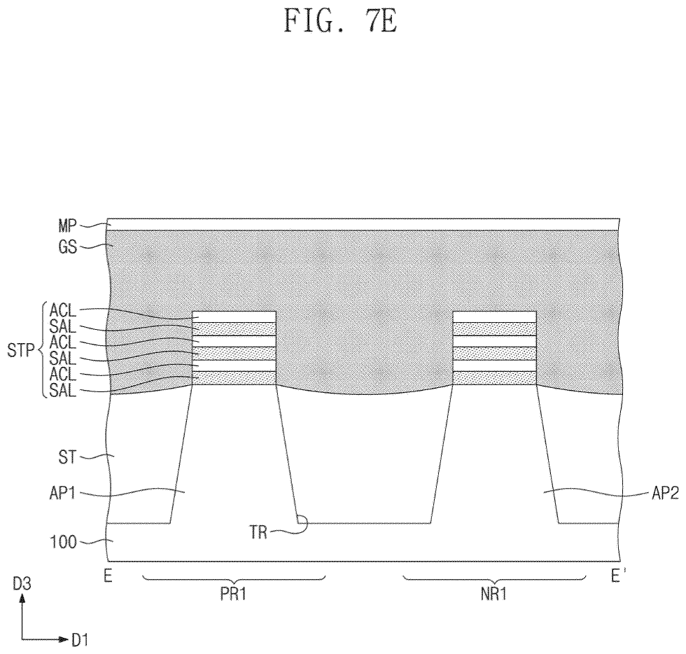

FIG. 4 is a plan view illustrating a semiconductor device according to one or more embodiments. FIGS. 5A to 5E are cross-sectional views illustrating a semiconductor device according to one or more embodiments. FIG. 5A illustrates a cross-sectional view taken along line A-A′ of FIG. 4. FIG. 5B illustrates a cross-sectional view taken along line B-B′ of FIG. 4. FIG. 5C illustrates a cross-sectional view taken along line C-C′ of FIG. 4. FIG. 5D illustrates a cross-sectional view taken along line D-D′ of FIG. 4. FIG. 5E illustrates a cross-sectional view taken along line E-E′ of FIG. 4. FIG. 5F is an enlarged view illustrating section M of FIG. 4 according to one or more embodiments. FIG. 5G is an enlarged view illustrating section N of FIG. 5C according to one or more embodiments. FIG. 5H is an enlarged view illustrating section O of FIG. 7D according to one or more embodiments. Description of aspects that are the same as or similar to those described above may be omitted.

Referring to FIGS. 4 and 5A to 5E, first and second single height cells SHC1 and SHC2 may be provided on a substrate 100. Each of the first and second single height cells SHC1 and SHC2 may include logic transistors included in a logic circuit. The substrate 100 may be a compound semiconductor substrate or a semiconductor substrate including silicon, germanium, or silicon-germanium.

The substrate 100 may include a first PMOSFET region PR1, a second PMOSFET region PR2, a first NMOSFET region NR1, and a second NMOSFET region NR2. Each of the first and second PMOSFET regions PR1 and PR2 may be an active region, and each of the first and second NMOSFET regions NR1 and NR2 may also be an active region. Each of the first and second PMOSFET and NMOSFET regions PR1, PR2, NR1, and NR2 may extend in a second direction D2 that is parallel to a top surface of the substrate 100 and that intersects a first direction D1.

A first active pattern AP1 and a second active pattern AP2 may be defined by a trench TR formed on an upper portion of the substrate 100. The first active pattern AP1 may be provided on each of the first and second PMOSFET regions PR1 and PR2. The second active pattern AP2 may be provided on each of the first and second NMOSFET regions NR1 and NR2. The first and second active patterns AP1 and AP2 may extend in the second direction D2. The first and second active patterns AP1 and AP2 may be portions of the substrate 100 that protrude from the top surface of the substrate 100 in a third direction D3 perpendicular to the top surface of the substrate 100.

A device isolation layer ST may fill the trench TR. The device isolation layer ST may include a silicon oxide layer. The device isolation layer ST may be disposed between the first active pattern AP1 and the second active pattern AP2.

First source/drain patterns SD1 may be provided on the first and second PMOSFET regions PR1 and PR2. The first source/drain patterns SD1 may be provided on the first active pattern AP1. The first source/drain patterns SD1 may be impurity regions of a first conductivity type (e.g., p-type). A first channel pattern CH1 may be interposed between a pair of first source/drain patterns SD1 that are adjacent in the second direction D2, and may be disposed on the first active pattern AP1. The first channel pattern CH1 may include semiconductor patterns SP1, SP2, and SP3 that are spaced apart from each other in the third direction D3 on the first active pattern AP1. The pair of first source/drain patterns SD1 may be connected to the semiconductor patterns SP1, SP2, and SP3 of the first channel pattern CH1.

Second source/drain patterns SD2 may be provided on the first and second NMOSFET regions NR1 and NR2. The second source/drain patterns SD2 may be provided on the second active pattern AP2. The second source/drain patterns SD2 may be impurity regions of a second conductivity type (e.g., n-type) different from the first conductivity type. A second channel pattern CH2 may be interposed between a pair of second source/drain patterns SD2 that are adjacent in the second direction D2, and may be disposed on the second active pattern AP2. The second channel pattern CH2 may include semiconductor patterns SP1, SP2, and SP3 that are spaced apart from each other in the third direction D3 on the second active pattern AP2. The pair of second source/drain patterns SD2 may be connected to the semiconductor patterns SP1, SP2, and SP3 of the second channel pattern CH2.

The first and second source/drain patterns SD1 and SD2 may be epitaxial patterns formed by a selective epitaxial growth process. For example, top surfaces of the first and second source/drain patterns SD1 and SD2 may be coplanar with those of the first and second channel patterns CH1 and CH2. For another example, top surfaces of the first and second source/drain patterns SD1 and SD2 may be higher than those of the first and second channel patterns CH1 and CH2.

The first source/drain pattern SD1 may include a semiconductor material (e.g., SiGe) whose lattice constant is greater than that of the first channel pattern CH1. Therefore, a pair of first source/drain patterns SD1 may provide the first channel pattern CH1 therebetween with a compressive stress. For example, the second source/drain pattern SD2 may include a semiconductor material (e.g., Si or SiC) whose lattice constant is the same as or less than that of the second channel pattern CH2. When the second source/drain pattern SD2 includes a semiconductor material whose lattice constant is less than that of the second channel pattern CH2, a pair of second source/drain patterns SD2 may provide the second channel pattern CH2 therebetween with a tensile stress.

Gate electrodes GE may be provided to extend in the first direction D1, while extending across the first and second active patterns AP1 and AP2. The gate electrodes GE may overlap the first and second channel patterns CH1 and CH2 in a vertical direction. Each of the gate electrodes GE may surround the top surface and opposite sidewalls of each of the first and second channel patterns CH1 and CH2.

The first single height cell SHC1 may have a first boundary BD1 and a second boundary BD2 that are opposite to each other in the second direction D2. The first and second boundaries BD1 and BD2 may extend in the first direction D1. The first single height cell SHC1 may have a third boundary BD3 and a fourth boundary BD4 that are opposite to each other in the first direction D1. The third and fourth boundaries BD3 and BD4 may extend in the second direction D2.

Gate cutting patterns CT may be disposed on the third and fourth boundaries BD3 and BD4 of the first single height cell SHC1. The gate cutting patterns CT may be disposed on a boundary in the second direction D2 of each of the first and second single height cells SHC1 and SHC2. In a plan view, the gate cutting patterns CT on the third and fourth boundaries BD3 and BD4 may be disposed to correspondingly overlap the gate electrodes GE. The gate cutting patterns CT may include a dielectric material, such as a silicon oxide layer or a silicon nitride layer.

The gate cutting pattern CT may separate the gate electrode GE on the first single height cell SHC1 from the gate electrode GE on the second single height cell SHC2. The gate cutting pattern CT may be interposed between the gate electrode GE on the first single height cell SHC1 and the gate electrode GE on the second single height cell SHC2 that are aligned with each other in the first direction D1. For example, the gate cutting pattern CT may divide the gate electrode GE extending in the first direction D1 into a plurality of gate electrodes GE.

The gate electrodes GE may extend in the first direction D1, while extending across the first and second channel patterns CH1 and CH2. The gate electrodes GE may overlap the first and second channel patterns CH1 and CH2 in a vertical direction. The gate electrode GE may include a first part PO1 interposed between the first semiconductor pattern SP1 and the active pattern AP1 or AP2, a second part PO2 interposed between the first semiconductor pattern SP1 and the second semiconductor pattern SP2, a third part PO3 interposed between the second semiconductor pattern SP2 and the third semiconductor pattern SP3, and a fourth part PO4 on the third semiconductor pattern SP3.

Referring to FIG. 5E, the gate electrode GE may be provided on a top surface TS, a bottom surface BS, and opposite sidewalls SW of each of the first, second, and third semiconductor patterns SP1, SP2, and SP3. For example, a transistor according to one or more embodiments may be a three-dimensional field effect transistor (e.g., multi-bridge channel FET (MBCFET) or gate-all-around FET (GAAFET)) in which the gate electrode GE three-dimensionally surrounds the first and second channel patterns CH1 and CH2.

A pair of gate spacers GS may be disposed on opposite sidewalls of the fourth part PO4 of the gate electrode GE. The gate spacers GS may extend in the first direction D1 along the gate electrode GE. The gate spacers GS may have top surfaces higher than that of the gate electrode GE. The top surfaces of the gate spacers GS may be coplanar with that of a first interlayer dielectric layer 110 which will be described below. For example, the gate spacers GS may include at least one of SiCN, SiCON, and SiN. For example, the gate spacers GS may each include a multi-layer formed of at least two selected from SiCN, SiCON, and SiN.

A gate capping pattern GP may be provided on the gate electrode GE. The gate capping pattern GP may extend in the first direction D1 along the gate electrode GE. The gate capping pattern GP may include a material having an etch selectivity with respect to first and second interlayer dielectric layers 110 and 120 which will be discussed below. For example, the gate capping pattern GP may include at least one selected from SiON, SiCN, SiCON, and SiN.

A gate dielectric layer GI may be interposed between the gate electrode GE and the first channel pattern CH1 and between the gate electrode GE and the second channel pattern CH2. The gate dielectric layer GI may cover the top surface TS, the bottom surface BS, and the opposite sidewalls SW of each of the first, second, and third semiconductor patterns SP1, SP2, and SP3. The gate dielectric layer GI may cover a top surface of the device isolation layer ST that underlies the gate electrode GE.

On the first and second NMOSFET regions NR1 and NR2, a dielectric pattern IP may be interposed between the gate dielectric layer GI and the second source/drain pattern SD2. The gate dielectric layer GI and the dielectric pattern IP may separate the gate electrode GE from the second source/drain pattern SD2. In contrast, on the first and second PMOSFET regions PR1 and PR2, the dielectric pattern IP may not be provided.

The gate electrode GE may include a first metal pattern and a second metal pattern on the first metal pattern. The first metal pattern may be provided on the gate dielectric layer GI and adjacent to the first, second, and third semiconductor patterns SP1, SP2, and SP3. A thickness and composition of the first metal pattern may be adjusted to achieve a desired threshold voltage of a transistor. For example, the first, second, and third parts PO1, PO2, and PO3 of the gate electrode GE may be formed of the first metal pattern. The first metal pattern and the second metal pattern may have different work functions from each other.

The first metal pattern may include a metal nitride layer. For example, the first metal pattern may include nitrogen (N) and at least one metal selected from titanium (Ti), tantalum (Ta), aluminum (Al), tungsten (W), and molybdenum (Mo). In addition, the first metal pattern may further include carbon (C). The first metal pattern may include a plurality of stacked metal layers.

The second metal pattern may include metal with a resistance that is less than that of the first metal pattern. For example, the second metal pattern may include at least one metal selected from tungsten (W), aluminum (Al), titanium (Ti), and tantalum (Ta). For example, the fourth part PO4 of the gate electrode GE may include the first metal pattern and the second metal pattern on the first metal pattern.

A first interlayer dielectric layer 110 may be provided on the substrate 100. The first interlayer dielectric layer 110 may cover the gate spacers GS and the first and second source/drain patterns SD1 and SD2. A top surface of the first interlayer dielectric layer 110 may be substantially coplanar with those of the gate capping patterns GP and those of the gate spacers GS.

A second interlayer dielectric layer 120 may be disposed on the first interlayer dielectric layer 110, covering the gate capping patterns GP. A third interlayer dielectric layer 130 may be provided on the second interlayer dielectric layer 120. A fourth interlayer dielectric layer 140 may be provided on the third interlayer dielectric layer 130. For example, the first to fourth interlayer dielectric layers 110 to 140 may include a silicon oxide layer.

Each of the first and second single height cells SHC1 and SHC2 may be provided on its opposite sides with a pair of separation structures DB that are opposite to each other in the second direction D2. For example, the pair of separation structures DB may be correspondingly provided on the first and second boundaries BD1 and BD2 of the first single height cell SHC1. The separation structure DB may extend in the first direction D1 parallel to the gate electrodes GE.

The separation structure DB may penetrate the first and second interlayer dielectric layers 110 and 120 to extend into the first and second active patterns AP1 and AP2. The separation structure DB may penetrate an upper portion of each of the first and second active patterns AP1 and AP2. The separation structure DB may electrically separate an active region of each of the first and second single height cells SHC1 and SHC2 from an active region of another cell.

Active contacts AC may be provided to penetrate the first and second interlayer dielectric layers 110 and 120 to come into electrical connection with the first and second source/drain patterns SD1 and SD2. A first active contact AC1 may be electrically connected to the first source/drain pattern SD1 of the first PMOSFET region PR1. A second active contact AC2 may be electrically connected to the second source/drain pattern SD2 of the first NMOSFET region NR1. A third active contact AC3 may be electrically connected to the first source/drain pattern SD1 of the second PMOSFET region PR2.

Each of the active contacts AC may be provided between a pair of gate electrodes GE. In a plan view, each of the active contacts AC may have a bar or linear shape that extends in the first direction D1.

The active contact AC may be a self-aligned contact. For example, the gate capping pattern GP and the gate spacer GS may be used to form the active contact AC in a self-alignment manner. For example, each of the active contacts AC may cover at least a portion of a sidewall of the gate spacer GS. Each of the active contacts AC may cover a portion of the top surface of the gate capping pattern GP.

Each of the active contacts AC may include a conductive pattern FM and a barrier pattern BM. The conductive pattern FM may include metal with a resistance that is low. The barrier pattern BM may conformally cover the conductive pattern FM. The barrier pattern BM may include a metal layer and a metal nitride layer. The metal layer may include at least one of titanium, tantalum, tungsten, nickel, cobalt, and platinum. The metal nitride layer may include at least one of a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

Silicide patterns SC may be correspondingly interposed between the active contacts AC and the first and second source/drain patterns SD1 and SD2. The active contacts AC may be electrically connected to through the silicide patterns SC to the first and second source/drain patterns SD1 and SD2. The silicide pattern SC may include metal silicide, for example, at least one of titanium silicide, tantalum silicide, tungsten silicide, nickel silicide, and cobalt silicide.

Referring further to FIGS. 4 and 5F to 5H, active cutting patterns ACP may be disposed between the active contacts AC. A first active cutting pattern ACP1 may be disposed between the first active contact AC1 and the second active contact AC2. A second active cutting pattern ACP2 may be disposed between the first active contact AC1 and the third active contact AC3.

At least a portion of each of the active cutting patterns ACP may overlap the gate electrode GE in a vertical direction. The active cutting patterns ACP may include a dielectric material. The first active cutting pattern ACP1 may electrically insulate the first active contact AC1 and the second active contact AC2 from each other. The second active cutting pattern ACP2 may electrically insulate the first active contact AC1 and the third active contact AC3 from each other. A lowermost surface of each of the active cutting patterns ACP may be located at a level lower than that of a lowermost surface of each of the active contacts AC.

Each of the active cutting patterns ACP may include a first cutting pattern CP1 that extends toward the substrate 100 and a second cutting pattern CP2 on a lateral surface and a bottom surface of the first cutting pattern CP1. The second cutting pattern CP2 may expose at least a portion of the lateral surface of the first cutting pattern CP1.

The first cutting pattern CP1 may have a first lateral surface S1 and a third lateral surface S3 that are opposite to each other in the first direction D1. The first lateral surface S1 and the third lateral surface S3 may correspondingly face the active contacts AC.

The first cutting pattern CP1 may have a fourth lateral surface S4 and a second lateral surface S2 that intersects the first lateral surface S1. The second lateral surface S2 and the fourth lateral surface S4 may be opposite to each other in the second direction D2.

The first lateral surface S1 and the third lateral surface S3 of the first cutting pattern CP1 may correspondingly contact with the active contacts AC. The first lateral surface S1 and the third lateral surface S3 of the first cutting pattern CP1 may be lateral surfaces exposed by the second cutting pattern CP2.

For example, the first lateral surface S1 of the first active cutting pattern ACP1 may contact the first active contact AC1. The third lateral surface S3 of the first active cutting pattern ACP1 may contact the second active contact AC2. A first lateral surface S1 of the second active cutting pattern ACP2 may contact the third active contact AC3. A third lateral surface S3 of the second active cutting pattern ACP2 may contact the first active contact AC1.

The first cutting pattern CP1 and the second cutting pattern CP2 may include different materials from each other. A dielectric constant of the first cutting pattern CP1 may be greater than that of the second cutting pattern CP2. The first cutting pattern CP1 may include silicon nitride, for example, SiN.

The second cutting pattern CP2 may cover the lateral surface and the bottom surface of the first cutting pattern CP1. The second cutting pattern CP2 may expose at least a portion of the lateral surface of the first cutting pattern CP1. A thickness CP2_W of the second cutting pattern CP2 may range, for example, from about 3 nm to about 5 nm. The thickness CP2_W of the second cutting pattern CP2 may be measured along the second direction D2 on the lateral surface of the first cutting pattern CP1.

The second cutting pattern CP2 may include a dielectric material including carbon. An amount of carbon in the second cutting pattern CP2 may range from about 5 mol % to about 20 mol % relative to 100 mol % of the dielectric material. The second cutting pattern CP2 may include silicon oxycarbide, for example, SiOC.

The second cutting pattern CP2 may include a first cutting portion P1 that covers the bottom surface and the lateral surface of the first cutting pattern CP1. The first cutting portion P1 may cover the bottom surface of the first cutting pattern CP1, and may also cover lower portions of the first, second, third, and fourth lateral surfaces S1, S2, S3, and S4 of the first cutting pattern CP1.

A top surface P1_U of the first cutting portion P1 may be located at a level lower than that of a top surface CP1_U of the first cutting pattern CP1. The top surface P1_U of the first cutting portion P1 may contact each of the active contacts AC (see FIGS. 5C and 5G).

A bottom surface P1_L of the first cutting portion P1 may be located at a level lower than that of a bottom surface CP1_L of the first cutting pattern CP1. The bottom surface P1_L of the first cutting portion P1 may be referred to as a bottom surface of the second cutting pattern CP2, and may also be referred to as a lowermost surface of each of the active cutting patterns ACP.

The second cutting pattern CP2 may include second cutting portions P2 that extend in the third direction D3 from the first cutting portion P1. The second cutting portions P2 may correspondingly extend onto upper portions of the second and fourth lateral surfaces S2 and S4 of the first cutting pattern CP1. The second cutting portions P2 may correspondingly expose upper portions of the first and third lateral surfaces S1 and S3 of the first cutting pattern CP1 (i.e., the upper portions of the first and third lateral surfaces S1 and S3 of the first cutting pattern CP1 may be exposed through the second cutting portions P2). The second cutting pattern CP2 may expose portions, on which the second cutting portions P2 are not provided, of the first and third lateral surfaces S1 and S3 of the first cutting pattern CP1 (i.e. portions, on which the second cutting portions P2 are not provided, of the first and third lateral surfaces S1 and S3 of the first cutting pattern CP1, may be exposed through the second cutting portions P2).

The second cutting portions P2 may be spaced apart in the second direction D2 from each other by a first distance P2_D1. The first distance P2_D1 may be greater than a width AC_W in the second direction D2 of each of the active contacts AC. Each of uppermost surfaces P2_U of the second cutting portions P2 may be coplanar with the top surface CP1_U of the first cutting pattern CP1. Each of uppermost surfaces P2_U of the second cutting portions P2 may be located at a level higher than that of the top surface P1_U of the first cutting portion P1.

According to one or more embodiments, the second cutting pattern CP2 may expose at least a portion of the lateral surface of the first cutting pattern CP1 (i.e., the portion of the lateral surface of the first cutting pattern CP1 may be exposed through the second cutting pattern CP2). Therefore, each of the active cutting patterns ACP may have a reduced size (e.g., a width in the first direction D1). Each of the active contacts AC has an increased area, and thus a semiconductor device may improve in electrical properties.

In addition, the second cutting pattern CP2 may have a dielectric constant less than that of the first cutting pattern CP1. There may thus be an improvement in capacitance between neighboring active contacts AC. Therefore, a semiconductor device with improved electrical properties may be provided.

Referring back to FIGS. 4 and 5A to 5E, gate contacts GC may be provided to penetrate the second interlayer dielectric layer 120 and the gate capping pattern GP to come into electrical connection with the gate electrodes GE. Each of the active contacts AC may have an upper portion adjacent to the gate contact GC, and an upper dielectric pattern UIP may fill the upper portion of the active contact AC. A bottom surface of the upper dielectric pattern UIP may be lower than that of the gate contact GC. For example, the upper dielectric pattern UIP may cause the active contact AC adjacent to the gate contact GC to have a top surface lower than the bottom surface of the gate contact GC. Therefore, a short-circuit resulting from contact between the gate contact GC and its adjacent active contact AC may be prevented. The gate contact GC may include at least one metal selected from, for example, aluminum, copper, tungsten, molybdenum, and cobalt.

The gate contact GC may include a conductive pattern FM and a barrier pattern BM. The conductive pattern FM may include metal whose resistance is low. The barrier pattern BM may conformally cover the conductive pattern FM.

A first metal layer M1 may be provided in the third interlayer dielectric layer 130. For example, the first metal layer M1 may include a first power line M1_R1, a second power line M1_R2, a third power line M1_R3, and first wiring lines M1_I. The lines M1_R1, M1_R2, M1_R3, and M1_I of the first metal layer M1 may parallelly extend in the second direction D2.

For example, the first and second power lines M1_R1 and M1_R2 may be correspondingly provided on the third and fourth boundaries BD3 and BD4 of the first single height cell SHC1. The first power line M1_R1 may extend in the second direction D2 along the third boundary BD3. The second power line M1_R2 may extend in the second direction D2 along the fourth boundary BD4.

The first metal layer M1 may further include first vias VI1. The first vias VI1 may be correspondingly provided below the lines M1_R1, M1_R2, M1_R3, and M1_I of the first metal layer M1. The active contact AC may be electrically connected through the first via VI1 to a wiring line of the first metal layer M1. The gate contact GC may be electrically connected through the first via VI1 to a wiring line of the first metal layer M1.

A second metal layer M2 may be provided in the fourth interlayer dielectric layer 140. The second metal layer M2 may include a plurality of second wiring lines M2_I. The second wiring lines M2_I of the second metal layer M2 may each have a linear or bar shape that extends in the first direction D1. For example, the second wiring lines M2_I may parallelly extend in the first direction D1.

The second metal layer M2 may further include second vias VI2 that are correspondingly provided below the second wiring lines M2_I. A certain line of the first metal layer M1 may be electrically through the second via VI2 to a corresponding line of the second metal layer M2.

The first and second metal layers M1 and M2 may have their wiring lines that include the same or different conductive materials. For example, the wiring lines of the first and second metal layers M1 and M2 may include at least one metallic material selected from aluminum, copper, tungsten, molybdenum, and cobalt. Other metal layers (e.g., M3, M4, M5, etc.) may be additionally stacked on the fourth interlayer dielectric layer 140. Each of the stacked metal layers may include lines for routing between cells.

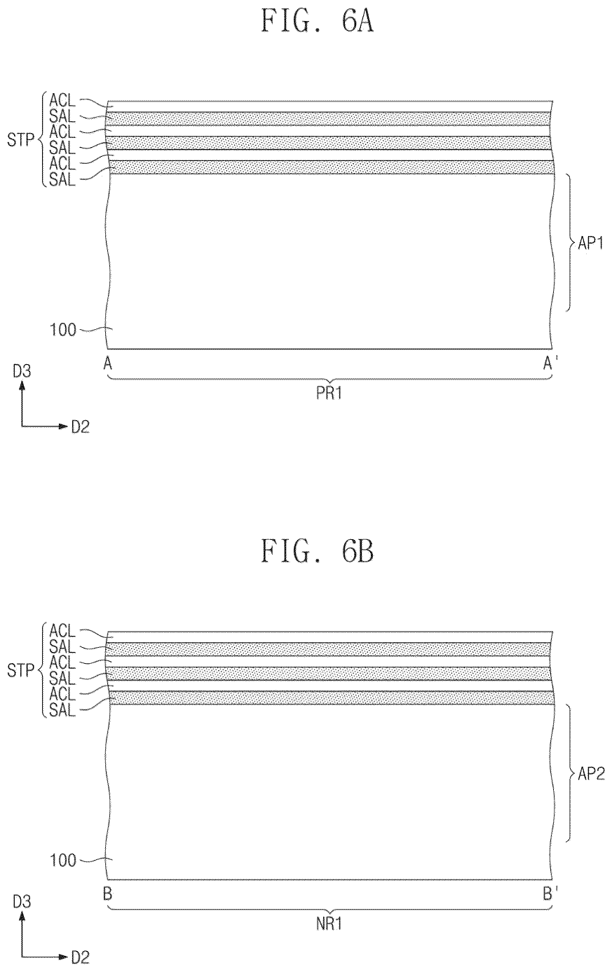

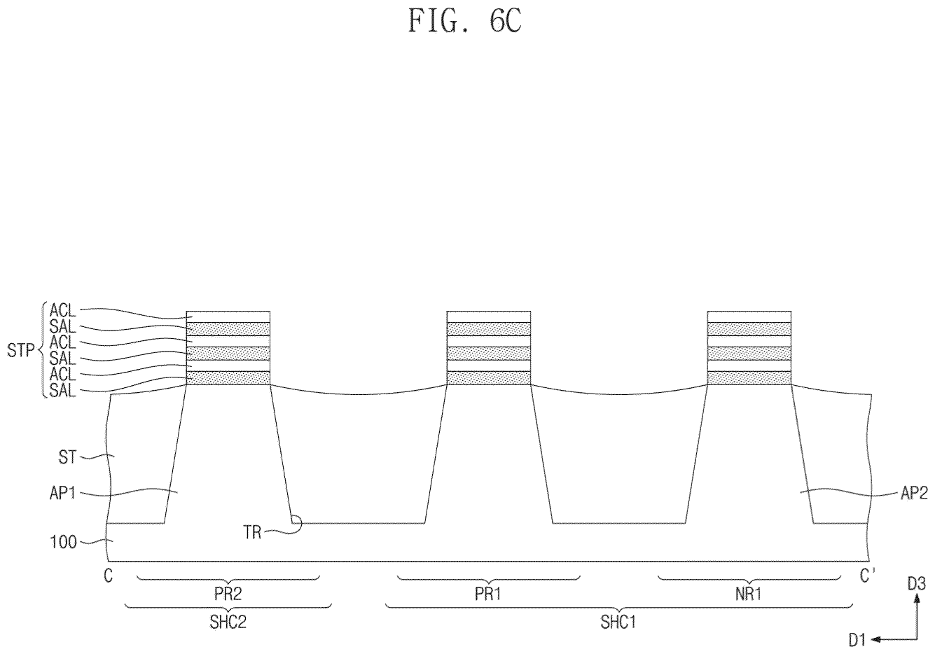

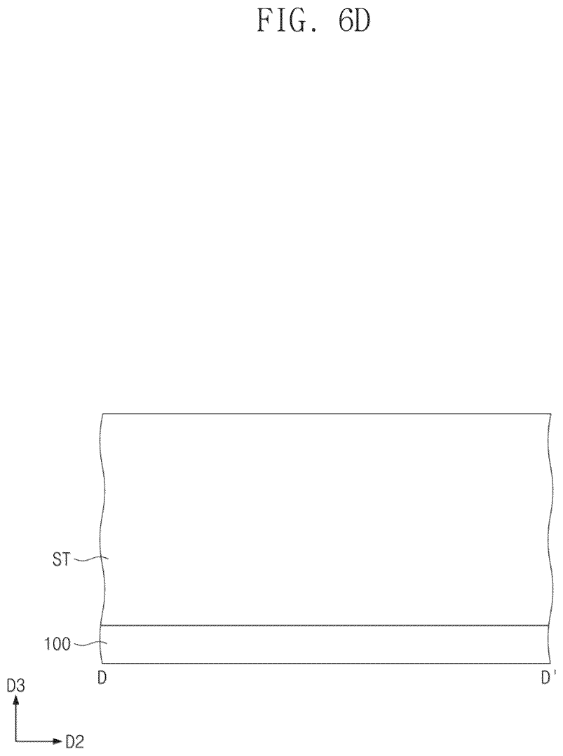

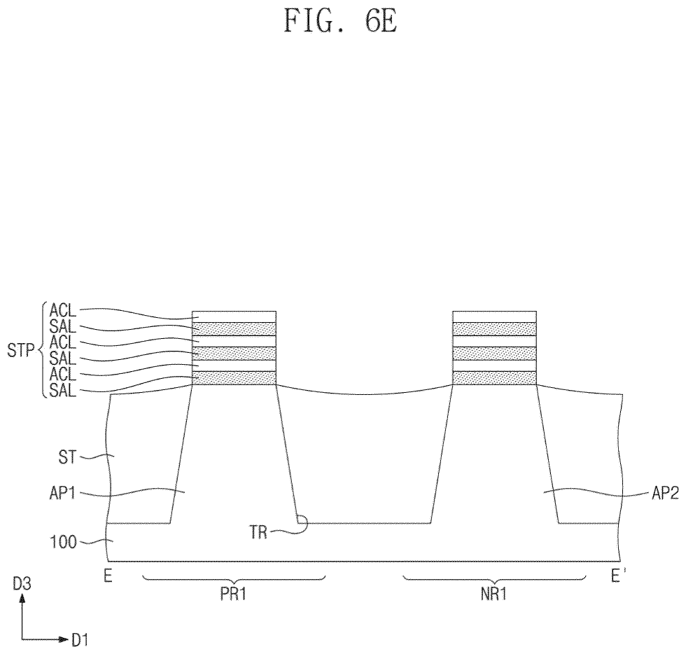

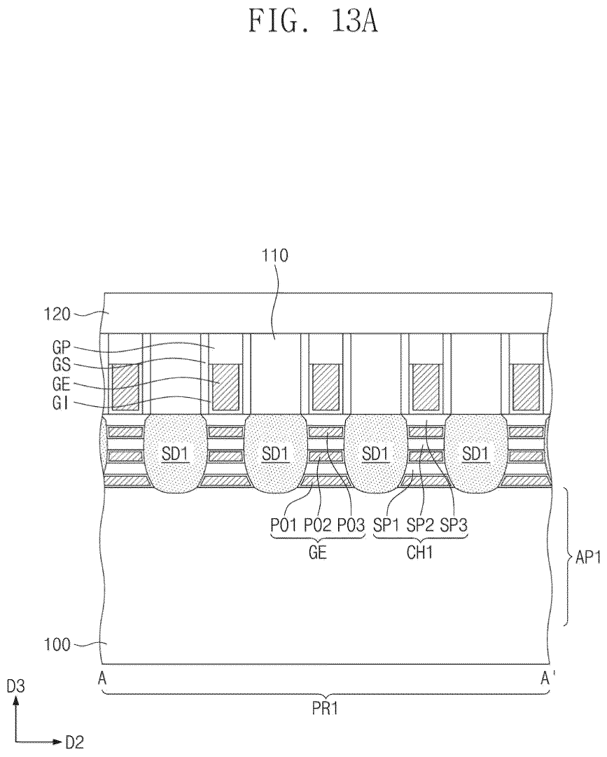

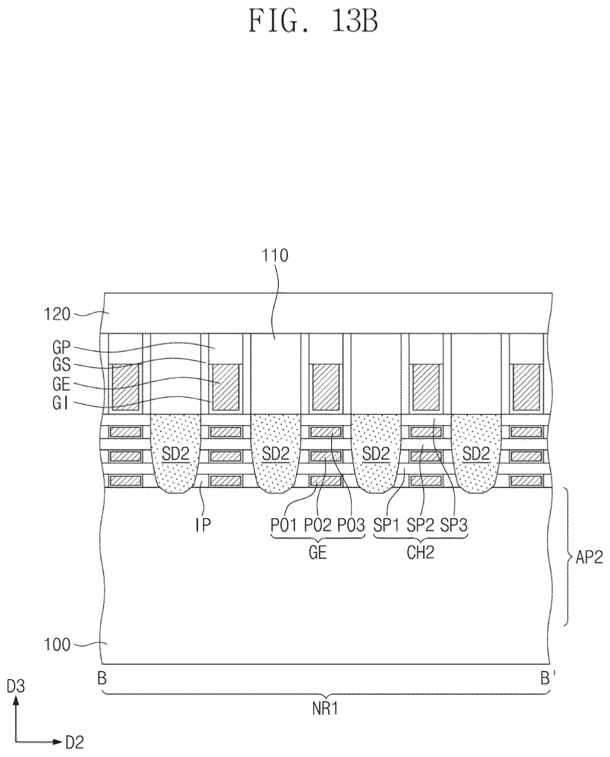

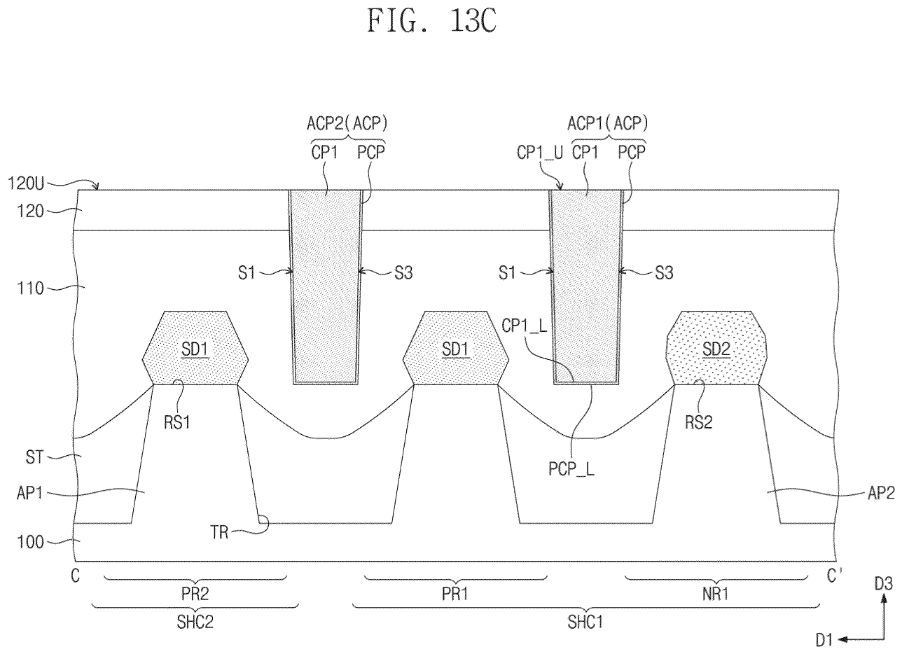

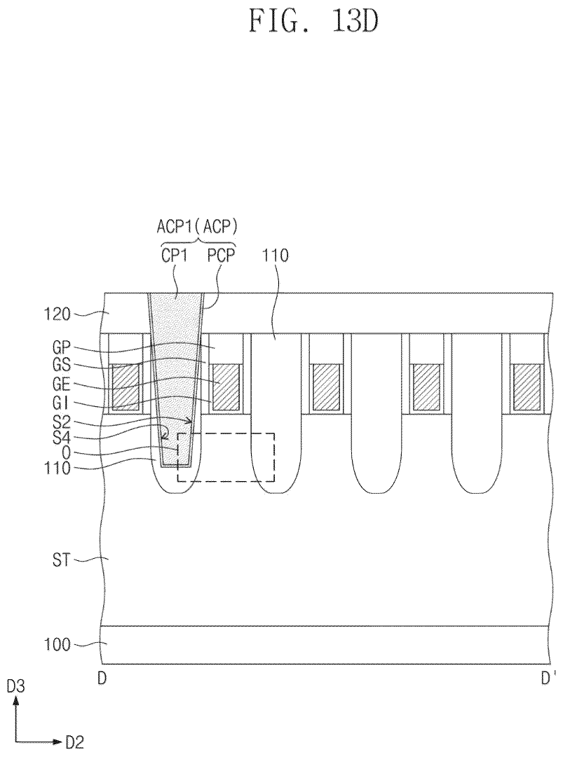

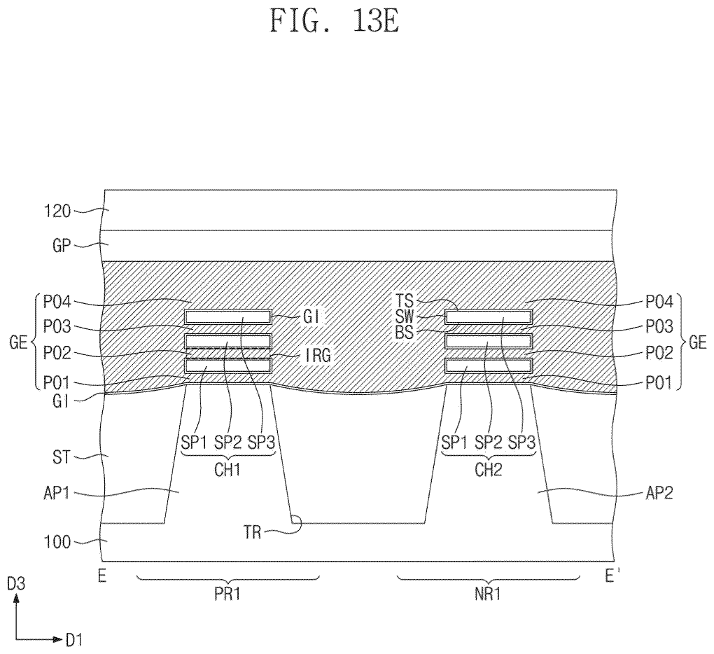

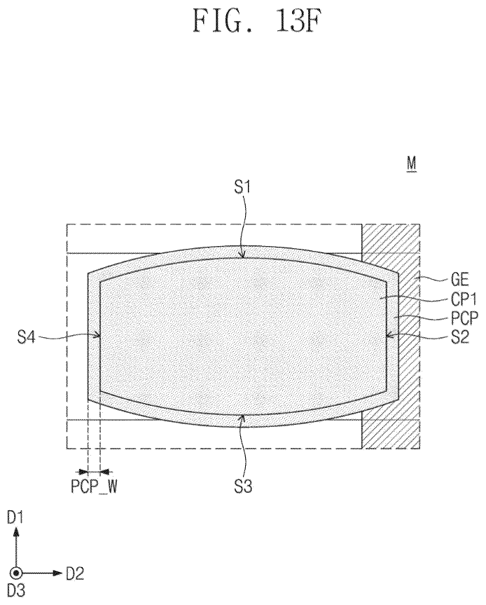

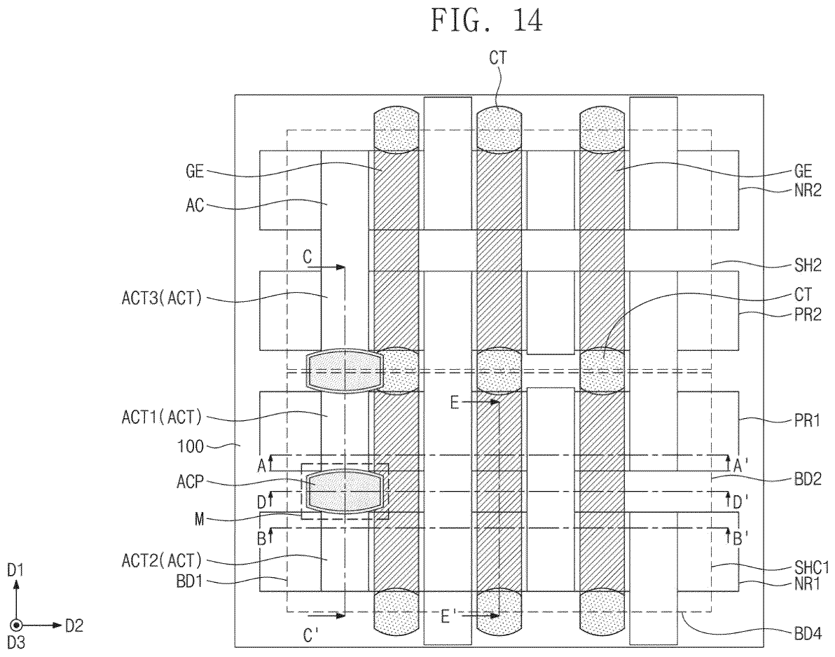

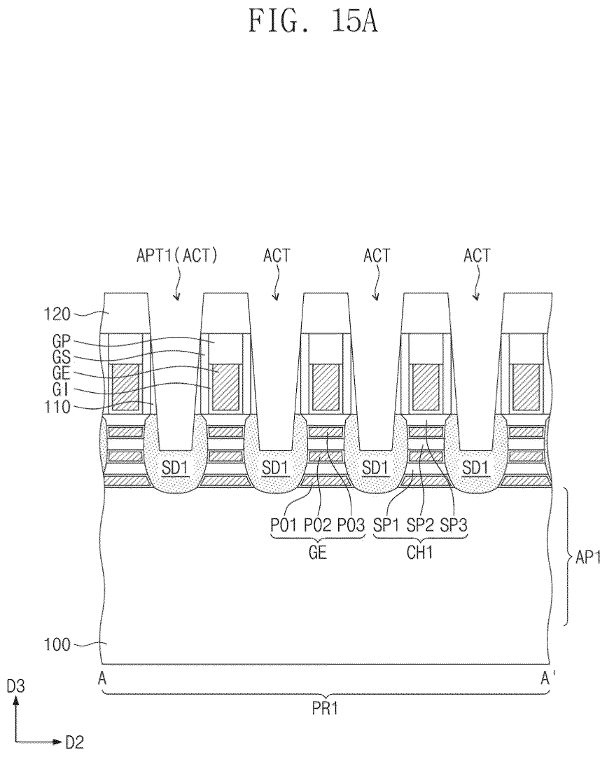

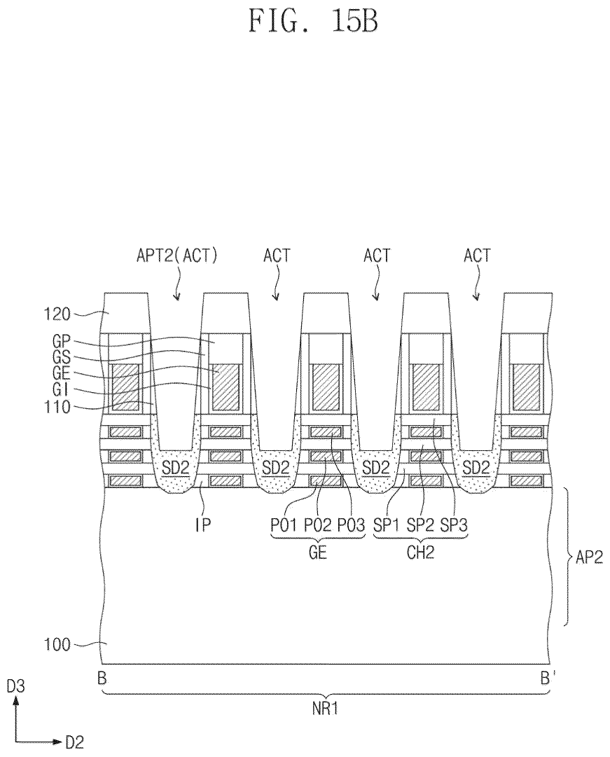

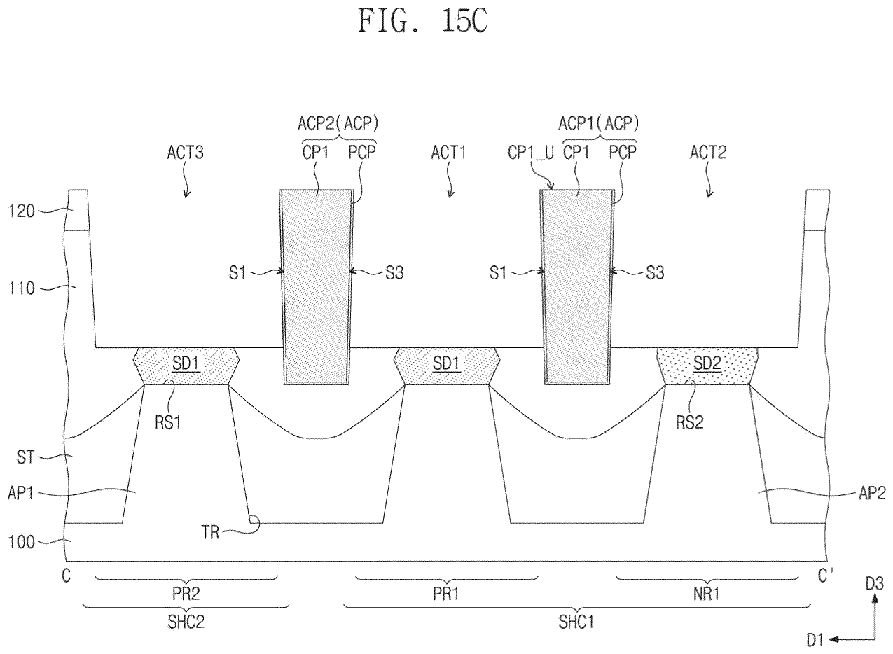

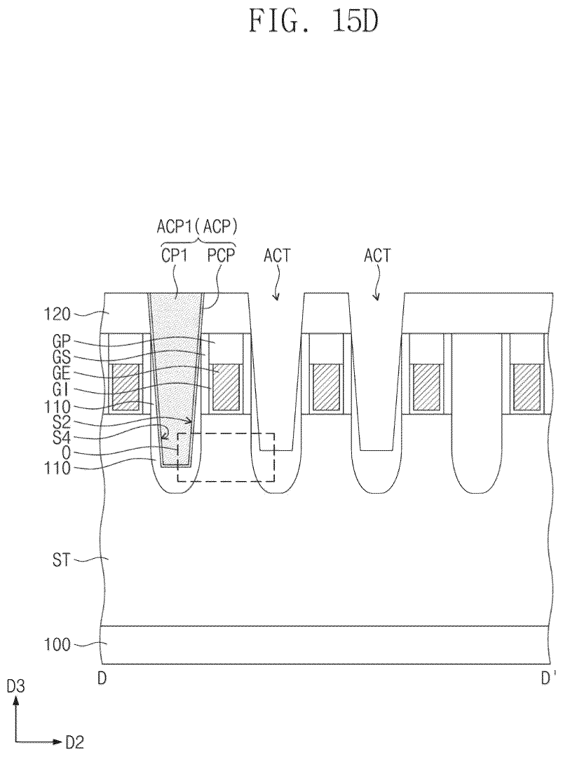

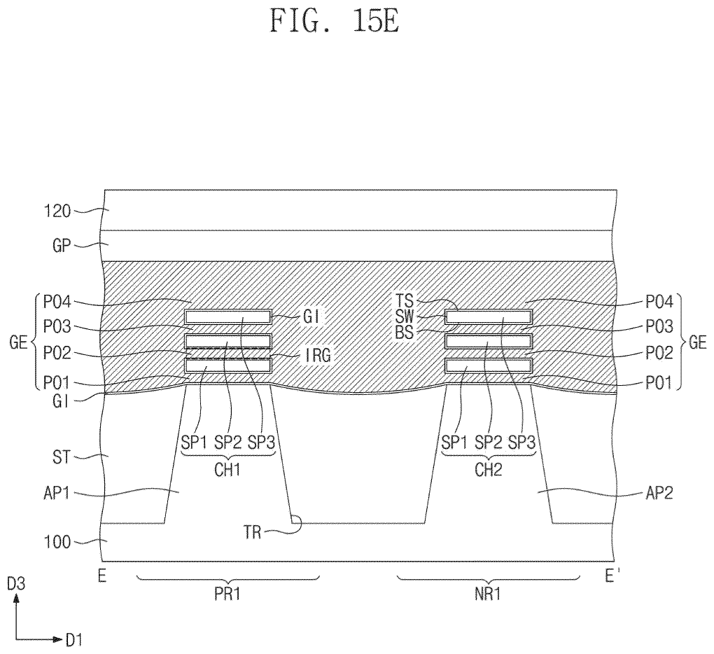

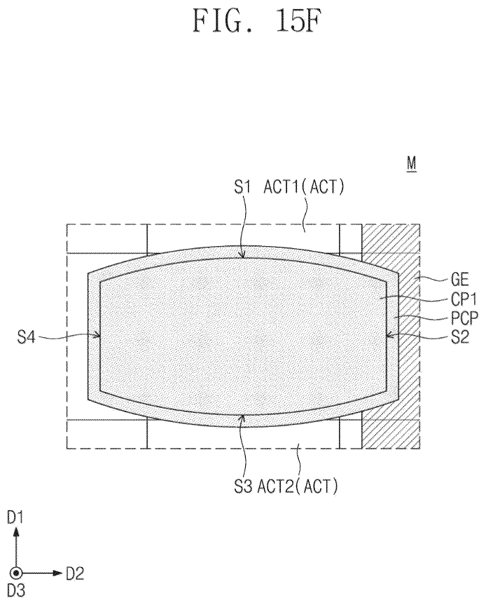

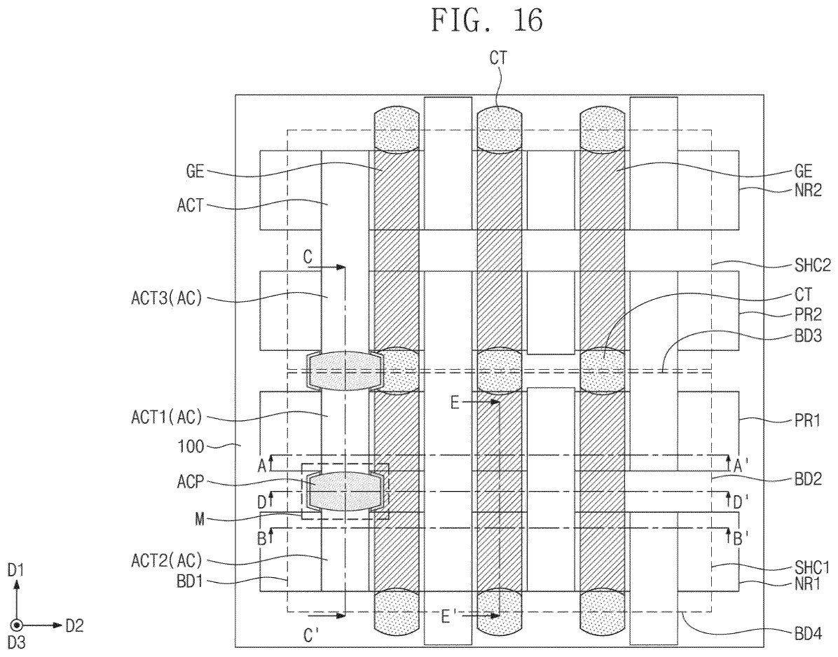

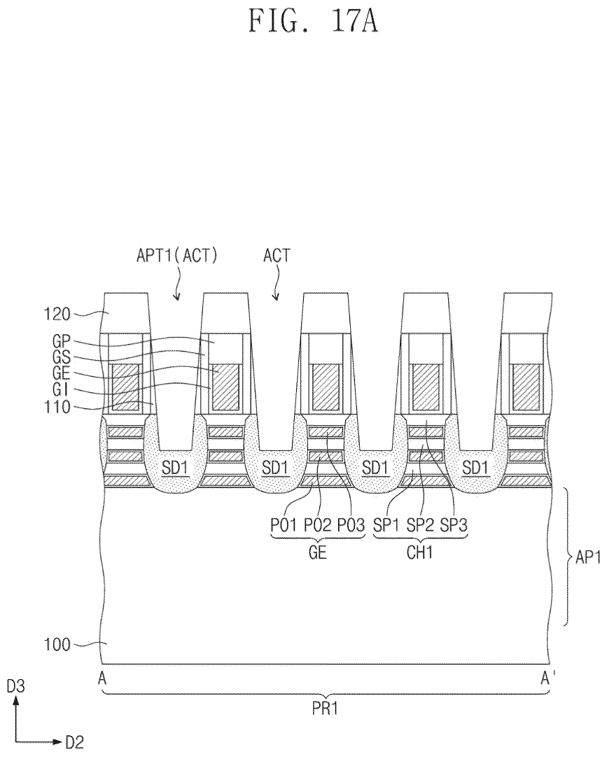

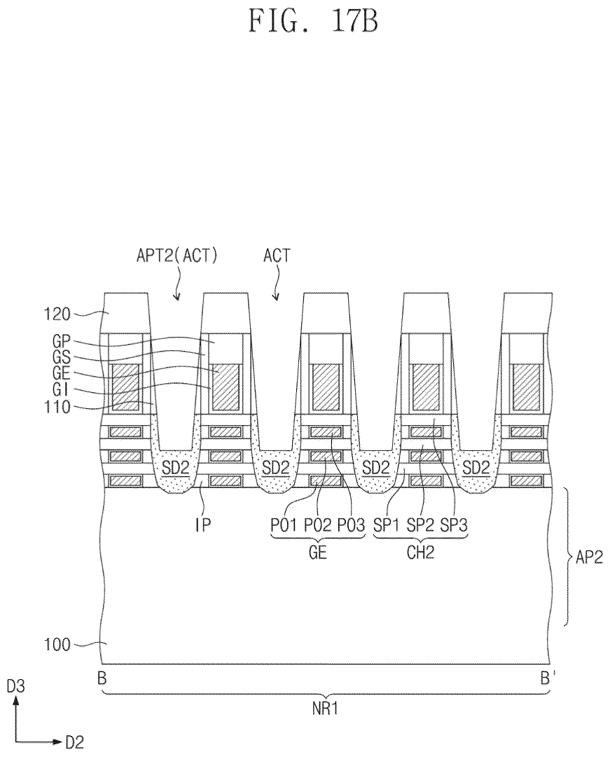

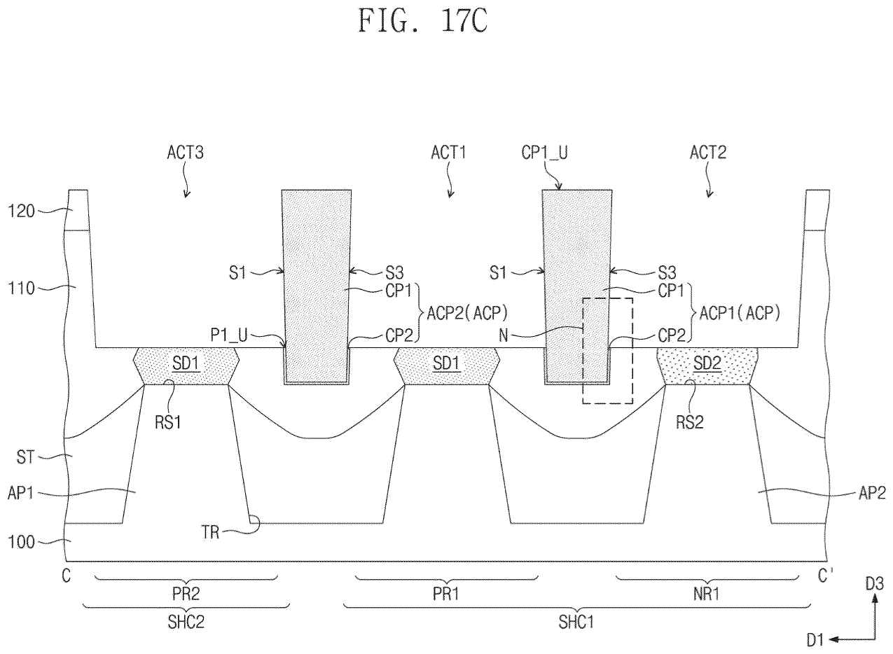

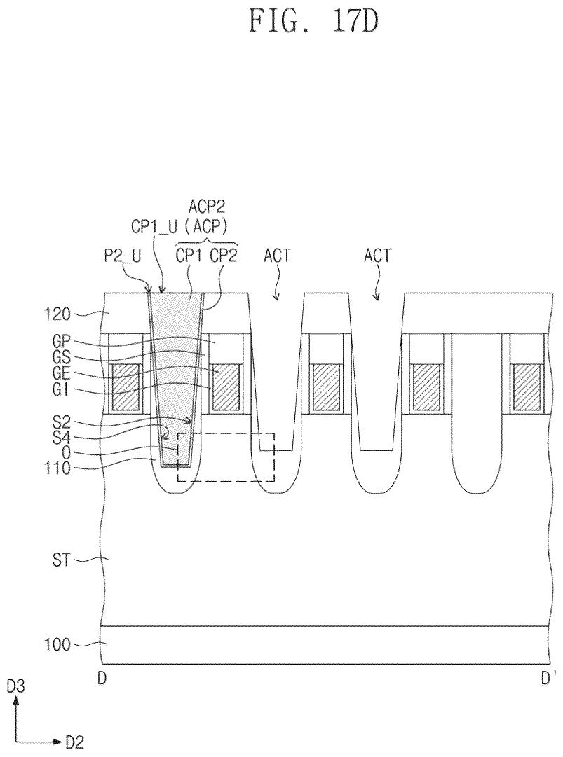

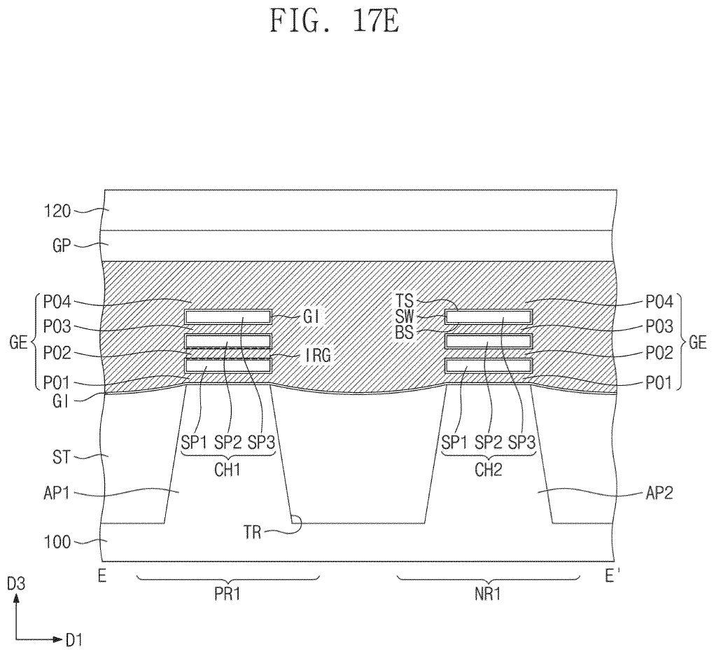

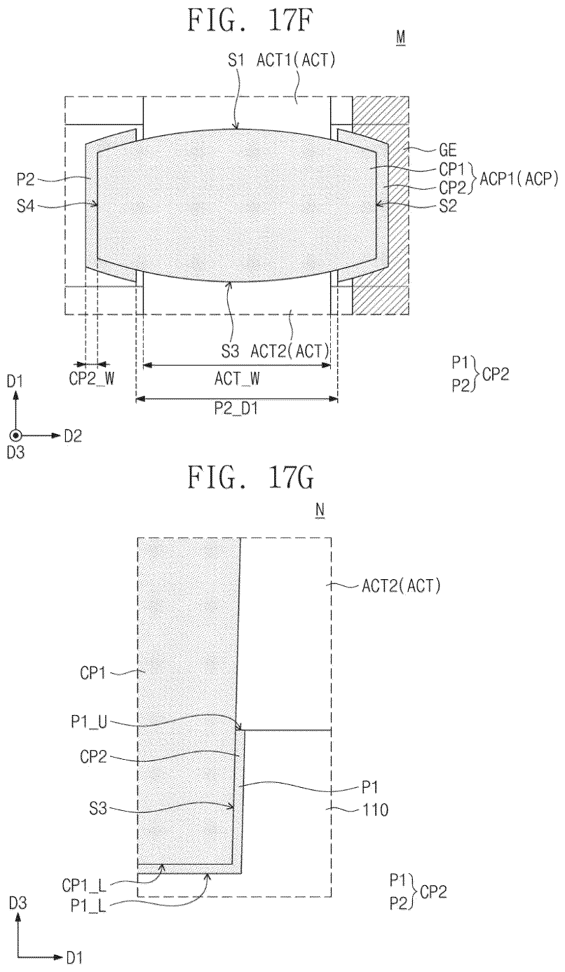

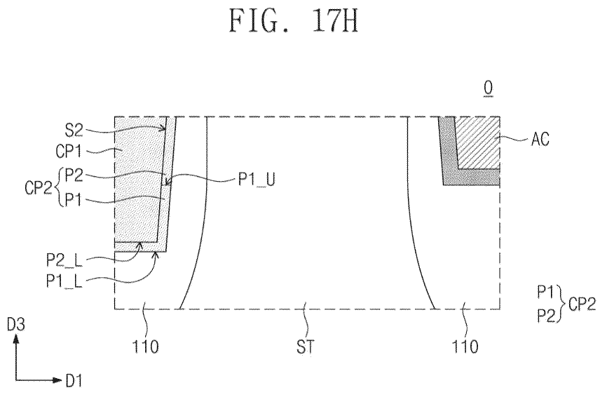

FIGS. 6A to 17H are diagrams illustrating a method of fabricating a semiconductor device according to one or more embodiments. FIGS. 6A to 11A illustrate cross-sectional views taken along line A-A′ of FIG. 4. FIGS. 6B to 11B illustrate cross-sectional views taken along line B-B′ of FIG. 4. FIGS. 6C to 11C illustrate cross-sectional views taken along line C-C′ of FIG. 4. FIGS. 6D to 11D illustrate cross-sectional views taken along line D-D′ of FIG. 4. FIGS. 6E to 11E illustrate cross-sectional views taken along line E-E′ of FIG. 4. FIGS. 12, 14, and 16 illustrate plan views showing a semiconductor device according to one or more embodiments. FIGS. 13A, 15A, and 17A illustrate cross-sectional views taken along line A-A′ of FIG. 16. FIGS. 13B, 15B, and 17B illustrate cross-sectional views taken along line B-B′ of FIG. 16. FIGS. 13C, 15C, and 17C illustrate cross-sectional views taken along line C-C′ of FIG. 16. FIGS. 13d, 15D, and 17D illustrate cross-sectional views taken along line D-D′ of FIG. 16. FIGS. 13E, 15E, and 17E illustrate cross-sectional views taken along line E-E′ of FIGS. 12, 14, and 16. FIG. 13F illustrates an enlarged view showing section M of FIG. 12. FIG. 15F illustrates an enlarged view showing section M of FIG. 14. FIG. 17F illustrates an enlarged view showing section M of FIG. 16. FIG. 17G illustrates an enlarged view showing section N of FIG. 17C. FIG. 17H illustrates an enlarged view showing section O of FIG. 17D. Description of aspects that are the same as or similar to those described above may be omitted.

Referring to FIGS. 6A to 6E, a substrate 100 may be provided which includes a first PMOSFET region PR1, a second PMOSFET region PR2, a first NMOSFET region NR1, and a second NMOSFET region NR2. The first NMOSFET region NR1 and the first PMOSFET region PR1 may define a first single height cell SHC1, and the second NMOSFET region NR2 and the second PMOSFET region PR2 may define a second single height cell SHC2.

The substrate 100 may be patterned to form first and second active patterns AP1 and AP2. The first active patterns AP1 may be formed on the first and second PMOSFET regions PR1 and PR2. The second active patterns AP2 may be formed on the first and second NMOSFET regions NR1 and NR2.

The formation of the first and second active patterns AP1 and AP2 may include, for example, forming a mask pattern on the substrate 100, and using the mask pattern as an etching mask to etch the substrate 100. The etching process may form a trench TR that defines the first active pattern AP1 and the second active pattern AP2.

The substrate 100 may be provided on its top surface with first sacrificial layers SAL and active layers ACL that are formed alternately stacked in a third direction D3 perpendicular to a top surface of the substrate 100. Thus, a plurality of stack patterns STP may be formed each of which includes the first sacrificial layers SAL and the active layers ACL that are alternately stacked. The first sacrificial layers SAL may include one of silicon (Si), germanium (Ge), and silicon-germanium (SiGe), and the active layers ACL may include another of silicon (Si), germanium (Ge), and silicon-germanium (SiGe). For example, the first sacrificial layers SAL may include silicon-germanium (SiGe) or germanium (Ge), and the active layers ACL may include silicon (Si).

A device isolation layer ST may be formed to fill the trench TR. For example, a dielectric layer may be formed on a front surface of the substrate 100, covering the first and second active patterns AP1 and AP2 and the stack patterns STP. The dielectric layer may be recessed, until the stack patterns STP are exposed, to form the device isolation layer ST.

Referring to FIGS. 7A to 7E, sacrificial patterns PP running across the stack patterns STP may be formed on the substrate 100. Each of the sacrificial patterns PP may be formed to have a linear or bar shape that extends in a first direction D1.

For example, the formation of the sacrificial patterns PP may include forming a sacrificial layer on the front surface of the substrate 100, forming first hardmask patterns MP on the sacrificial layer, and using the first hardmask patterns MP as an etching mask to pattern the sacrificial layer. The sacrificial layer may include polysilicon.

A pair of gate spacers GS may be formed on opposite sidewalls of each of the sacrificial patterns PP. The formation of the gate spacers GS may include conformally forming a gate spacer layer on the front surface of the substrate 100 and anisotropically etching the gate spacer layer.

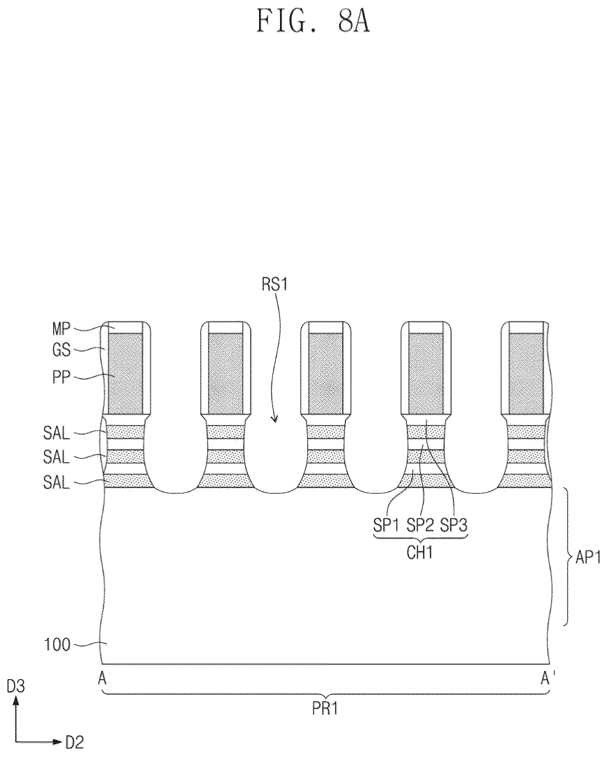

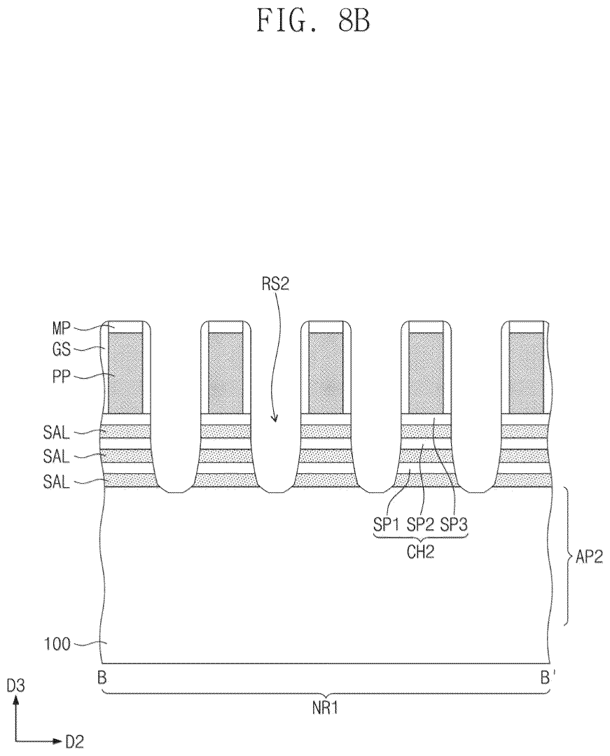

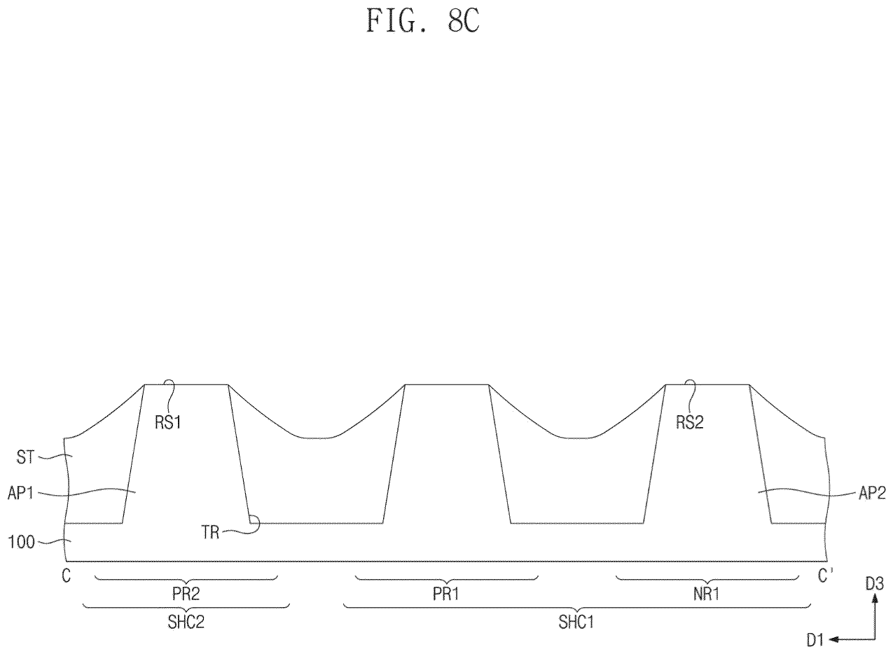

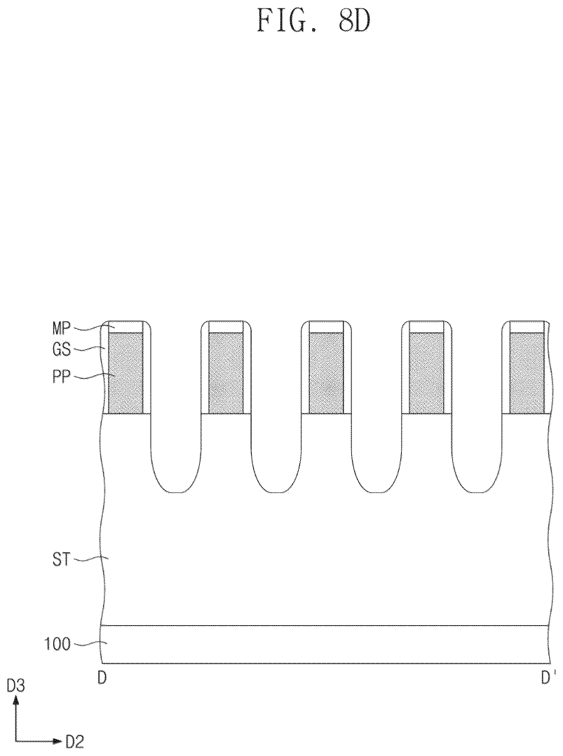

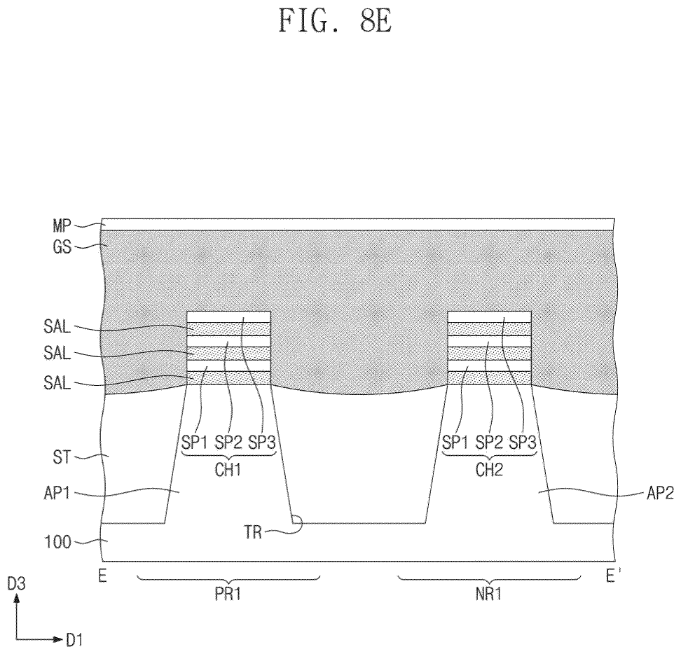

Referring to FIGS. 8A to 8D, first recesses RS1 may be formed in the stack pattern STP on the first active pattern AP1. Second recesses RS2 may be formed in the stack pattern STP on the second active pattern AP2. The formation of the first and second recesses RS1 and RS2 may further recess the device isolation layer ST on opposite sides of each of the first and second active pattern AP1 and AP2.

For example, the first hardmask patterns MP and the gate spacers GS may be used as an etching mask to etch the stack pattern STP on the first active pattern AP1, with the result that the first recesses RS1 may be formed. The first recess RS1 may be formed between a pair of sacrificial patterns PP. The second recesses RS2 in the stack pattern STP on the second active pattern AP2 may be formed by the same method used for the formation of the first recesses RS1.

The active layers ACL may be formed into first, second, and third semiconductor patterns SP1, SP2, and SP3 that are sequentially stacked between neighboring first recesses RS1. The active layers ACL may be formed into first, second, and third semiconductor patterns SP1, SP2, and SP3 that are sequentially stacked between neighboring second recesses RS2. A first channel pattern CH1 may be constituted by the first, second, and third semiconductor patterns SP1, SP2, and SP3 between neighboring first recesses RS1. A second channel pattern CH2 may be constituted by the first, second, and third semiconductor patterns SP1, SP2, and SP3 between neighboring second recesses RS2.

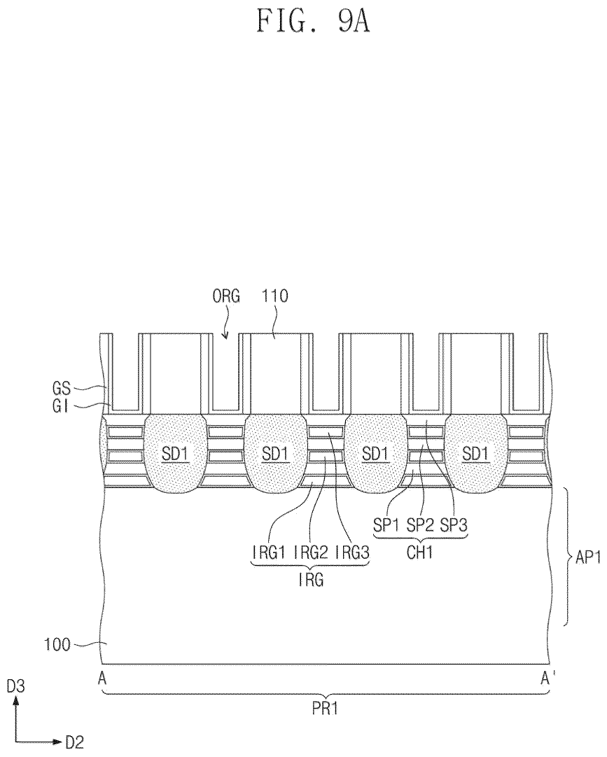

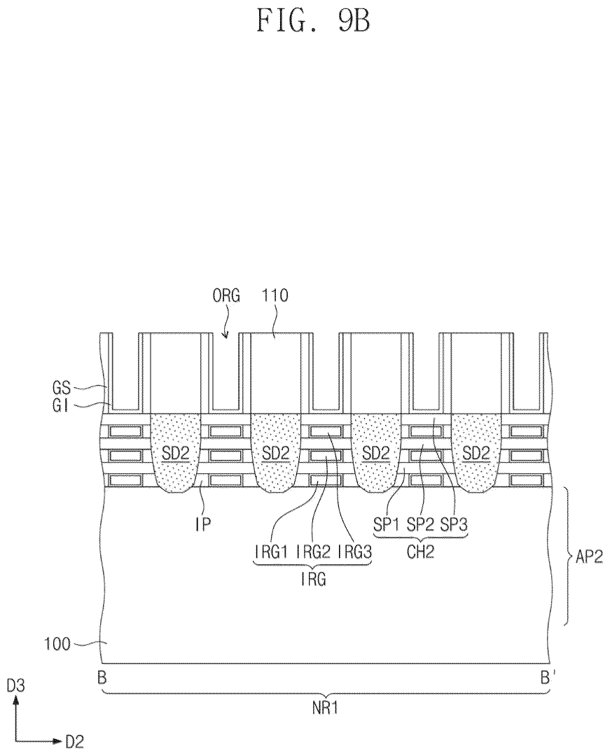

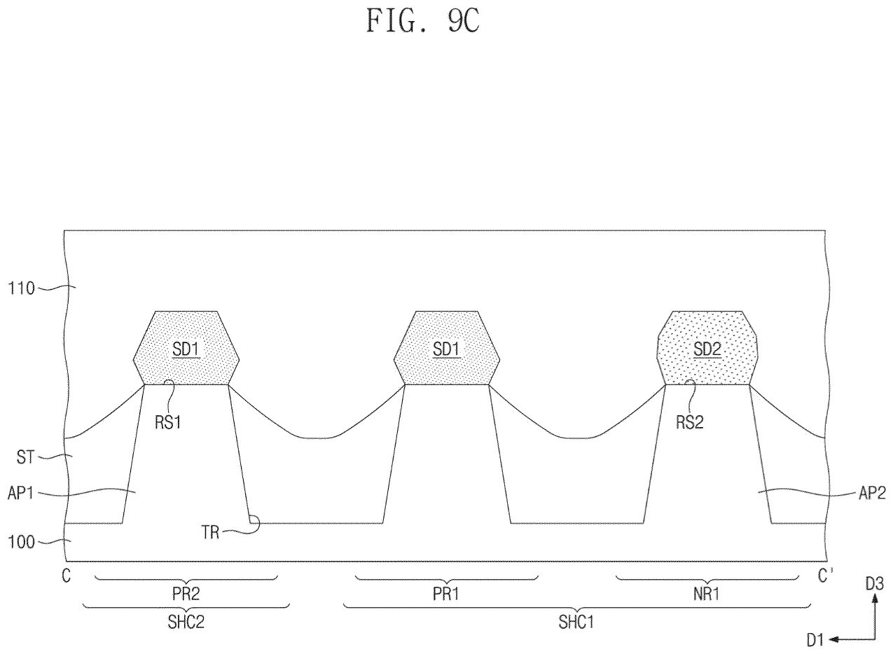

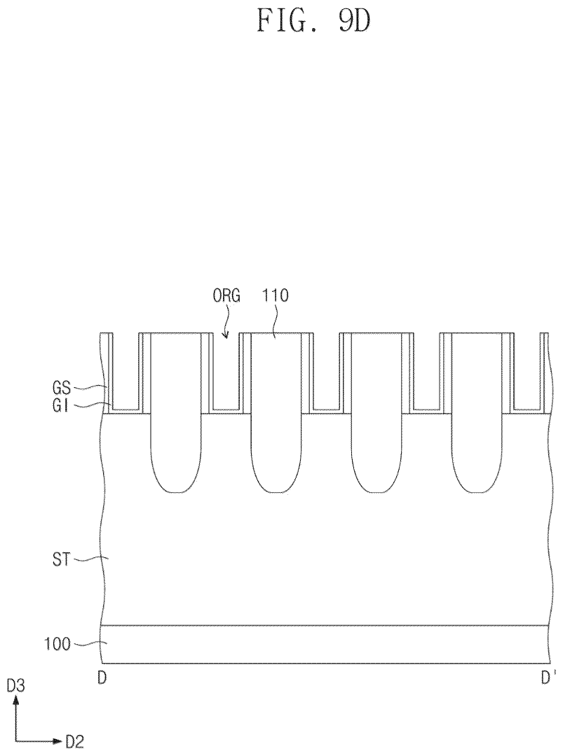

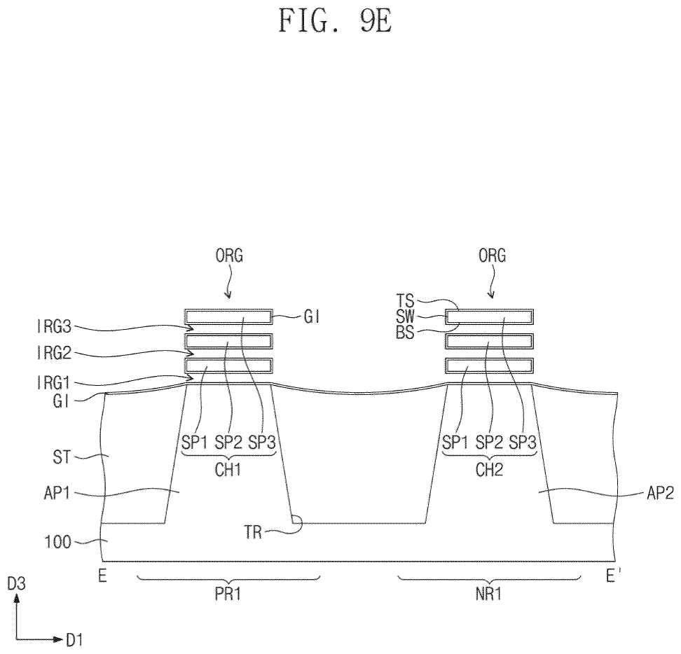

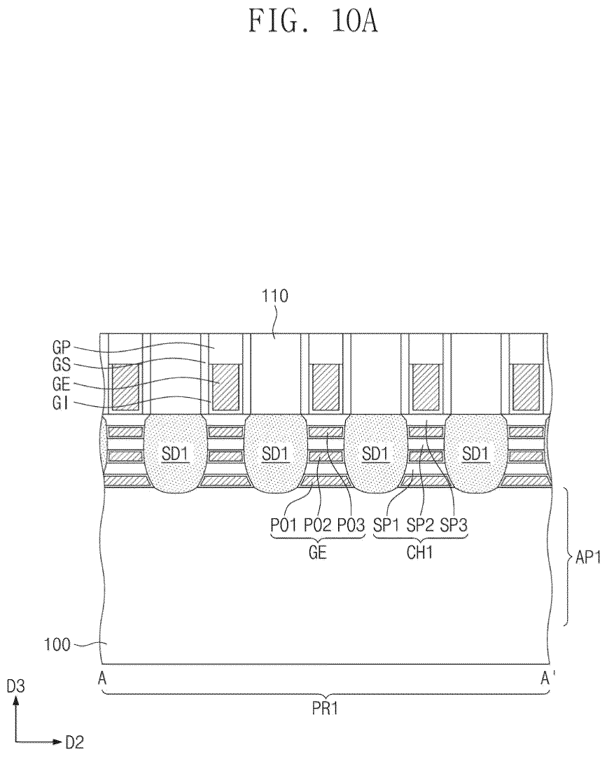

Referring to FIGS. 9A to 9E, first source/drain patterns SD1 may be correspondingly formed in the first recesses RS1. For example, a first selective epitaxial growth (SEG) process may be performed in which an inner wall of the first recess RS1 is used as a seed layer to form the first source/drain pattern SD1. The first SEG process may include chemical vapor deposition (CVD) or molecular beam epitaxy (MBE).

The first source/drain pattern SD1 may include a semiconductor element (e.g., SiGe) whose lattice constant is greater than that of a semiconductor element of the substrate 100. Impurities may be in-situ implanted during the first SEG process. Alternatively, after the formation of the first source/drain pattern SD1, impurities may be implanted into the first source/drain pattern SD1. The first source/drain pattern SD1 may be doped to have a first conductivity type (e.g., p-type).

Second source/drain patterns SD2 may be correspondingly formed in the second recesses RS2. For example, a second SEG process may be performed in which an inner wall of the second recess RS2 is used as a seed layer to form the second source/drain pattern SD2. For example, the second source/drain pattern SD2 may include the same semiconductor element (e.g., Si) as that of the substrate 100. The second source/drain pattern SD2 may be doped to have a second conductivity type (e.g., n-type). A dielectric pattern IP may be formed between the second source/drain pattern SD2 and the first sacrificial layers SAL.

A first interlayer dielectric layer 110 may be formed to cover the first and second source/drain patterns SD1 and SD2, the first hardmask patterns MP, and the gate spacers GS. The first interlayer dielectric layer 110 may be planarized until top surfaces of the sacrificial patterns PP are exposed. An etch-back or chemical mechanical polishing (CMP) process may be employed to planarize the first interlayer dielectric layer 110. During the planarization process, the first hardmask patterns MP may be all removed.

The exposed sacrificial patterns PP may be selectively removed. The removal of the sacrificial patterns PP may form an outer region ORG that exposes the first and second channel patterns CH1 and CH2. The removal of the sacrificial patterns PP may include performing a wet etching process using an etchant that selectively etches polysilicon.

The first sacrificial layers SAL exposed through the outer region ORG may be selectively removed to form inner regions IRG. For example, an etching process that selectively etches the first sacrificial layers SAL may be performed such that only the first sacrificial layers SAL may be removed while leaving the first, second, and third semiconductor patterns SP1, SP2, and SP3. The etching process may have a high etch rate for silicon-germanium having a relatively high germanium concentration.

The etching process may remove the first sacrificial layers SAL on the first and second active patterns AP1 and AP2. The etching process may be a wet etching process. An etching material used for the etching process may promptly etch the first sacrificial layer SAL whose germanium concentrate is relatively high.

As the first sacrificial layers SAL are selectively removed, only the first, second, and third semiconductor patterns SP1, SP2, and SP3 may remain on each of the first and second active patterns AP1 and AP2. The removal of the first sacrificial layers SAL may form the first, second, and third inner regions IRG1, IRG3, and IRG3.

A gate dielectric layer GI may be formed on the exposed first, second, and third semiconductor patterns SP1, SP2, and SP3. The gate dielectric layer GI may be formed to surround each of the first, second, and third semiconductor patterns SP1, SP2, and SP3.

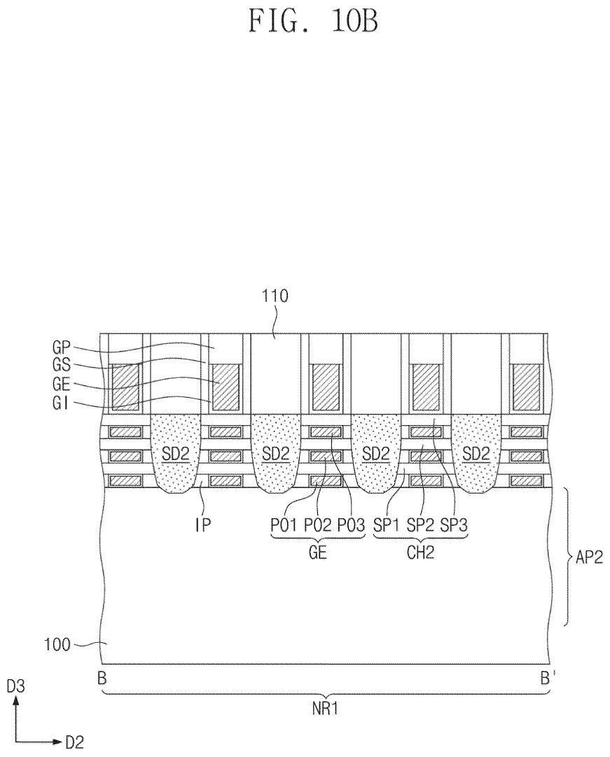

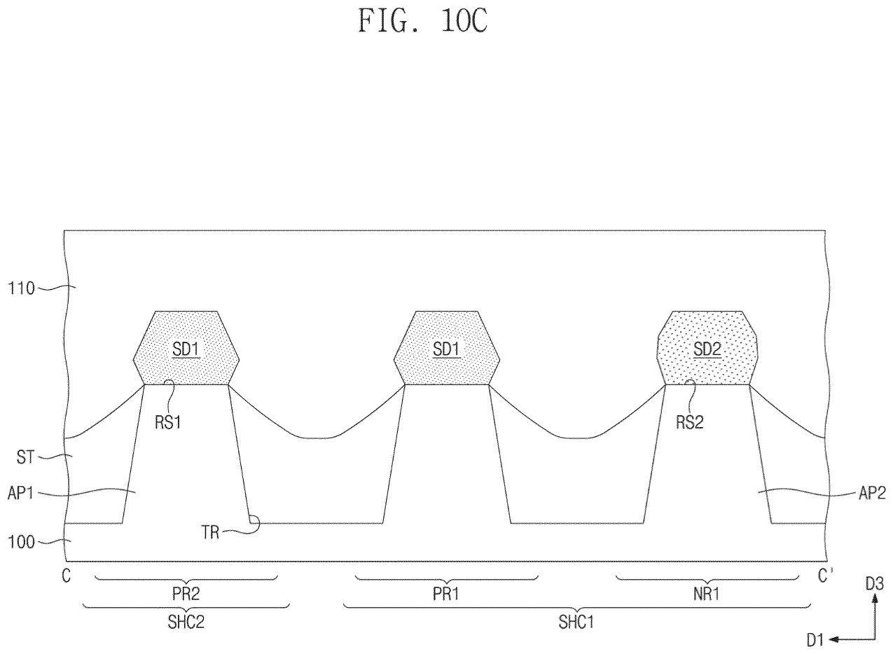

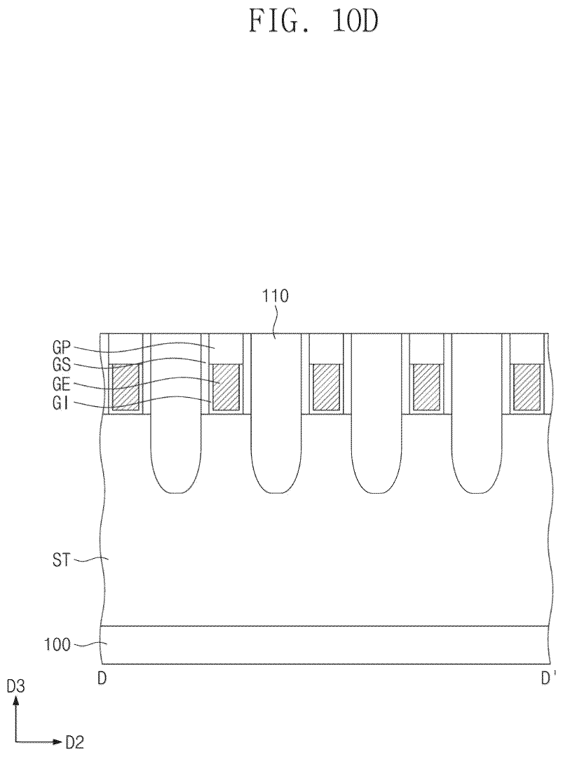

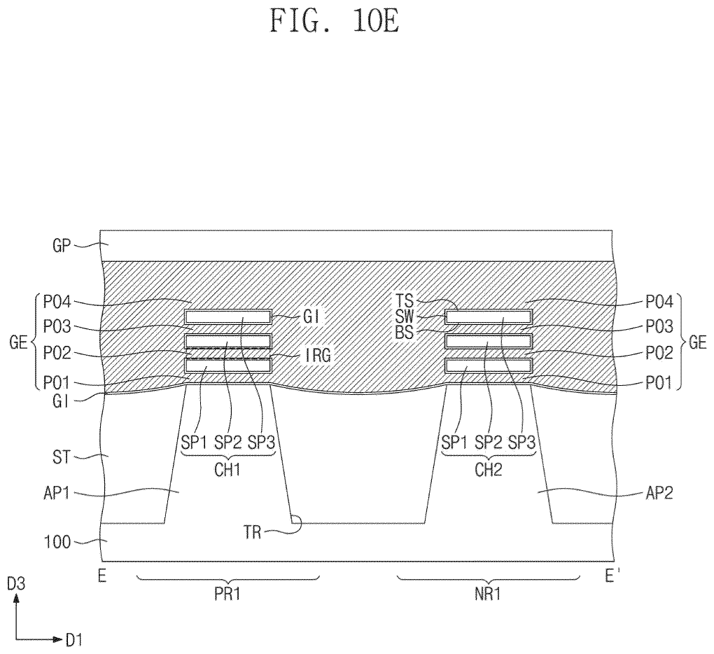

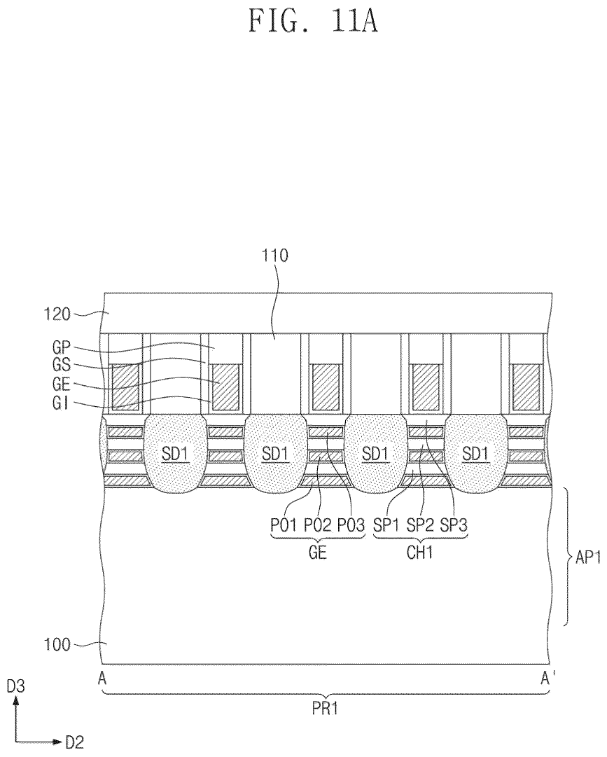

Referring to FIGS. 10A to 10E, the gate electrode GE may include first, second, and third parts PO1, PO2, and PO3 that are respectively formed in the first, second, and third inner regions IRG1, IRG2, and IRG3, and may also include a fourth part PO4 formed in the outer region ORG. The gate electrode GE may be recessed to have a reduced height. A gate capping pattern GP may be formed on the recessed gate electrode GE. Gate cutting patterns CT may be disposed on a boundary parallel to a second direction D2 of each of the first and second single height cells SHC1 and SHC2.

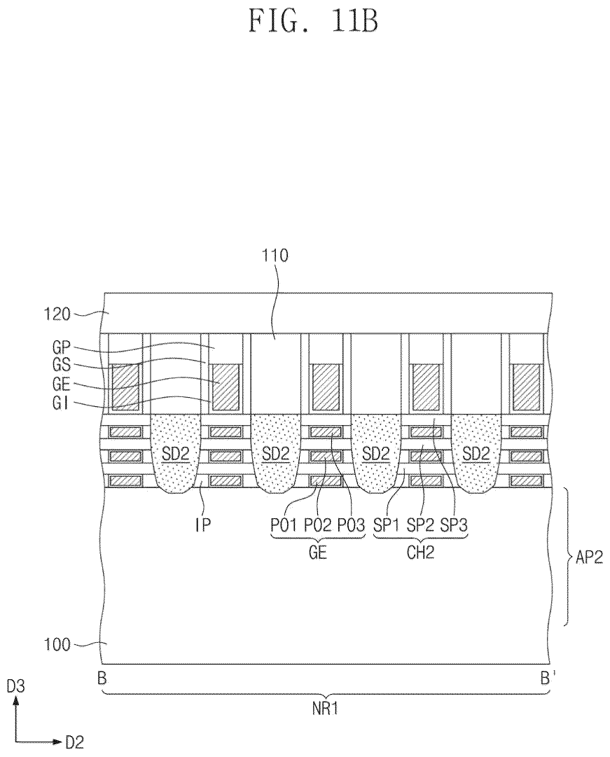

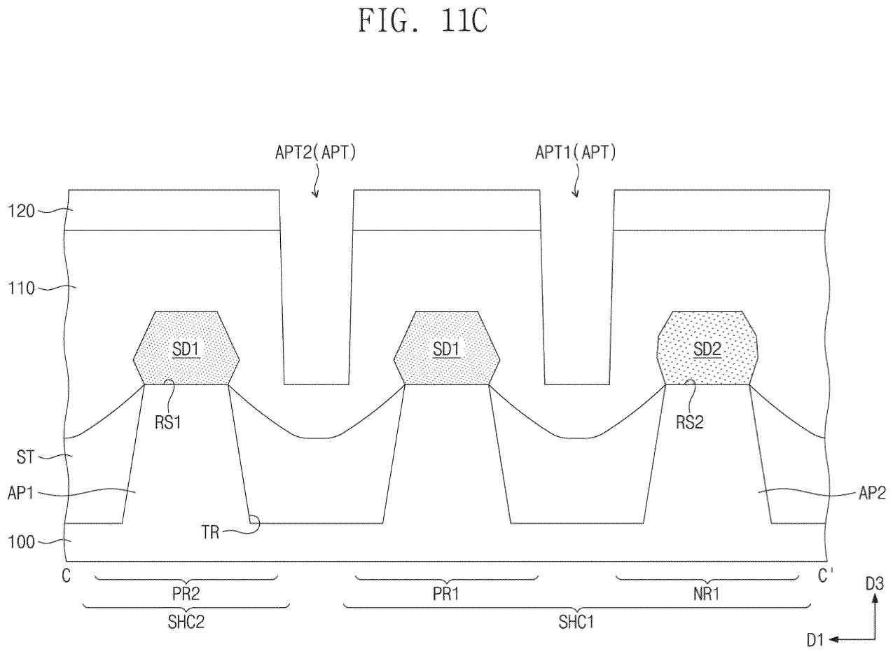

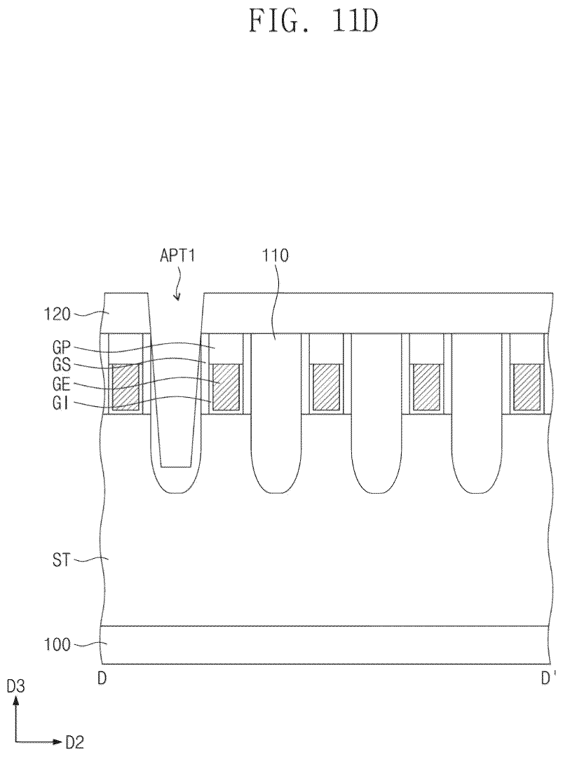

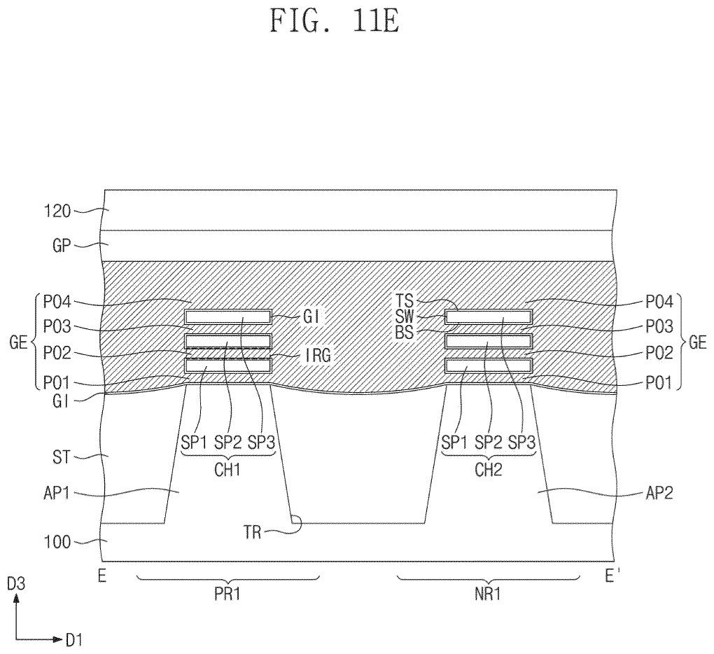

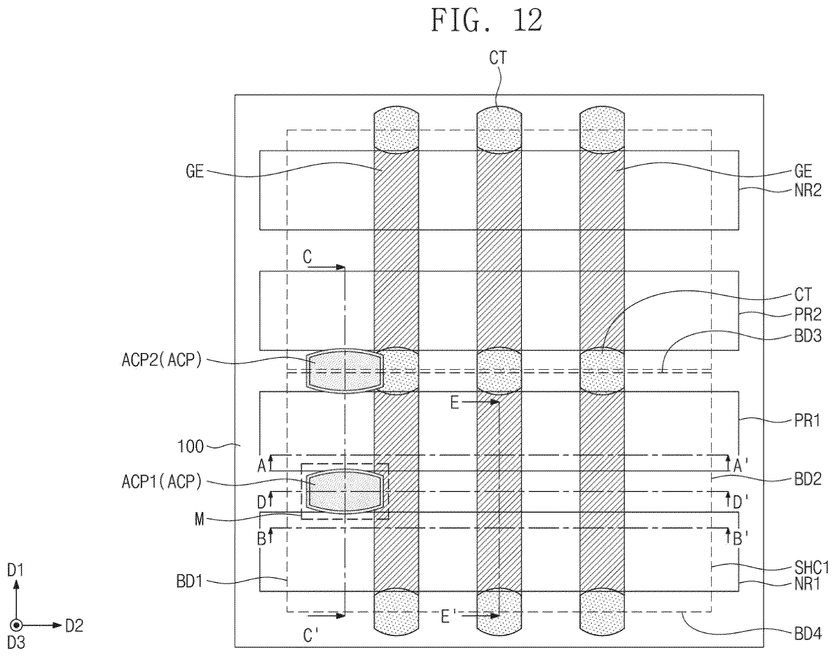

Referring to FIGS. 11A to 11E, a second interlayer dielectric layer 120 may be formed on the first interlayer dielectric layer 110. The second interlayer dielectric layer 120 may be formed on the gate capping pattern GP.

Cutting trenches APT may be formed to penetrate the second interlayer dielectric layer 120 and the first interlayer dielectric layer 110. Each of the cutting trenches APT may be formed between the gate electrodes GE. At least a portion of each of the cutting trenches APT may vertically overlap the gate electrode GE.

A first cutting trench APT1 may be formed between the first source/drain pattern SD1 of the first PMOSFET region PR1 and the second source/drain pattern SD2 of the first NMOSFET region NR1. A second cutting trench APT2 may be formed between the first source/drain pattern SD1 of the first PMOSFET region PR1 and the first source/drain pattern SD1 of the second PMOSFET region PR2.

The formation of the cutting trenches APT may include, for example, forming a first mask pattern on the second interlayer dielectric layer 120, using the first mask pattern as an etching mask to etch the second interlayer dielectric layer 120 and the first interlayer dielectric layer 110.

Referring to FIGS. 12 and 13A to 13E, active cutting patterns ACP may fill the cutting trenches APT. At least a portion of each of the active cutting patterns ACP may overlap the gate electrode GE in a vertical direction.

A first active cutting pattern ACP1 may be formed between the first source/drain pattern SD1 of the first PMOSFET region PR1 and the second source/drain pattern SD2 of the first NMOSFET region NR1. A second active cutting pattern ACP2 may be formed between the first source/drain pattern SD1 of the first PMOSFET region PR1 and the first source/drain pattern SD1 of the second PMOSFET region PR2.

Each of the active cutting patterns ACP may include a first cutting pattern CP1 and a preliminary cutting pattern PCP that covers a lateral surface and a bottom surface of the first cutting pattern CP1. The first cutting pattern CP1 and the preliminary cutting pattern PCP may include different materials from each other.

A dielectric constant of the first cutting pattern CP1 may be greater than that of the preliminary cutting pattern PCP. The first cutting pattern CP1 may include silicon nitride, for example, SiN. The preliminary cutting pattern PCP may include a dielectric material including carbon. An amount of carbon in the preliminary cutting pattern PCP may range from about 5 mol % to about 20 mol % relative to 100 mol % of the dielectric material. The preliminary cutting pattern PCP may include silicon oxycarbide, for example, SiOC.

The first cutting pattern CP1 may have a first lateral surface S1 and a third lateral surface S3 that are opposite to each other. The first lateral surface S1 and the third lateral surface S3 may face the first and second source/drain patterns SD1 and SD2. The first lateral surface S1 and the third lateral surface S3 may be opposite to each other in the first direction D1.

For example, the first lateral surface S1 of the first active cutting pattern ACP1 may face the first source/drain pattern SD1 of the first PMOSFET region PR1. The third lateral surface S3 of the first active cutting pattern ACP1 may face the second source/drain pattern SD2 of the first NMOSFET region NR1.

A first lateral surface S1 of the second active cutting pattern ACP2 may face the first source/drain pattern SD1 of the second PMOSFET region PR2. A third lateral surface S3 of the second active cutting pattern ACP2 may face the first source/drain pattern SD1 of the first PMOSFET region PR1.

The first cutting pattern CP1 may have a second lateral surface S2 across from the first lateral surface S1, and may also have a fourth lateral surface S4 opposite to the second lateral surface S2. The second lateral surface S2 and the fourth lateral surface S4 may be opposite to each other in the second direction D2.

The preliminary cutting pattern PCP may cover the lateral surface and the bottom surface of the first cutting pattern CP1. The preliminary cutting pattern PCP may cover all of the first, second, third, and fourth lateral surfaces S1, S2, S3, and S4 of the first cutting pattern CP1. A bottom surface PCP_L of the preliminary cutting pattern PCP may be located at a level lower than that of a bottom surface CP1_L of the first cutting pattern CP1. A thickness PCP_W of the preliminary cutting pattern PCP may range, for example, from about 3 nm to about 5 nm. The thickness PCP_W of the preliminary cutting pattern PCP may be measured along the second direction D2 on the lateral surface of the first cutting pattern CP1.

The formation of the active cutting patterns ACP may include, for example, forming the preliminary cutting pattern PCP in the cutting trenches APT, forming on the preliminary cutting pattern PCP the first cutting pattern CP1 to fill each of the cutting trenches APT, and performing a planarization process until the second interlayer dielectric layer 120 is exposed. The planarization process cause that a top surface CP1_U of the first cutting pattern CP1 is coplanar with a top surface 120U of the second interlayer dielectric layer 120.

Referring to FIGS. 14 and 15A to 15E, active trenches ACT may be formed to penetrate the second interlayer dielectric layer 120 and the first interlayer dielectric layer 110.

A first active trench ACT1 may be formed on the first source/drain pattern SD1 of the first PMOSFET region PR1. The first active trench ACT1 may expose a top surface of the first source/drain pattern SD1. A second active trench ACT2 may be formed on the second source/drain pattern SD2 of the first NMOSFET region NR1. The second active trench ACT2 may expose a top surface of the second source/drain pattern SD2. A third active trench ACT3 may be formed on the first source/drain pattern SD1 of the second PMOSFET region PR2. The third active trench ACT3 may expose a top surface of the first source/drain pattern SD1.

Referring still to FIGS. 15C, 15D, and 15F, the first active cutting pattern ACP1 may be interposed between the first active trench ACT1 and the second active trench ACT2. The first active trench ACT1 and the second active trench ACT2 may expose a lateral surface of the first active cutting pattern ACP1. The preliminary cutting pattern PCP may be exposed which is provided on the first lateral surface S1 and the third lateral surface S3 of the first active cutting pattern ACP1.

The second active cutting pattern ACP2 may be interposed between the first active trench ACT1 and the third active trench ACT3. The first active trench ACT1 and the third active trench ACT3 may expose a lateral surface of the second active cutting pattern ACP2. The preliminary cutting pattern PCP may be exposed which is provided on the first lateral surface S1 and the third lateral surface S3 of the second active cutting pattern ACP2.

The formation of the active trenches ACT may include, for example, forming a second mask pattern on the second interlayer dielectric layer 120, using the second mask pattern as an etching mask to etch the second interlayer dielectric layer 120 and the first interlayer dielectric layer 110.

According to one or more embodiments, each of the first active cutting pattern ACP1 and the second active cutting pattern ACP2 may include the preliminary cutting pattern PCP. There may thus be a reduced distance (e.g., a distance in the first direction D1) between the first active cutting pattern ACP1 and the second active cutting pattern ACP2.

The distance may be decreased to reduce failure where the top surfaces of the first and second source/drain patterns SD1 and SD2 are not exposed in the etching process. Accordingly, a method of fabricating a semiconductor device with improved reliability may be provided.

Referring to FIGS. 16 and 17A to 17H, an ashing process and a wet etching process may be performed to remove impurities. The ashing process and the wet etching process may remove impurities produced in the etching process for forming the active trenches ACT.

The ashing process and the wet etching process may remove the exposed preliminary cutting pattern PCP. The ashing process may cause a reduction in carbon amount of the exposed preliminary cutting pattern PCP. The wet etching process may cause a removal of the exposed preliminary cutting pattern PCP.

For example, a carbon amount of the preliminary cutting pattern PCP may range from about 5 mol % to about 20 mol % relative to 100 mol % of the dielectric material. The ashing process may allow the exposed preliminary cutting pattern PCP to have a reduced carbon amount. A carbon amount of the preliminary cutting pattern PCP may range from about 0.01 mol % to about 3 mol % relative to 100 mol % of the dielectric material.

Therefore, the exposed preliminary cutting pattern PCP and the preliminary cutting pattern PCP may have different etch selectivity from each other. The wet etching process may etch the exposed preliminary cutting pattern PCP.

There may thus be exposed the first lateral surface S1 and the third lateral surface S3 of the first cutting pattern CP1. The first active trench ACT1 and the second active trench ACT2 may expose the first lateral surface S1 and the third lateral surface S3 of the first active cutting pattern ACP1. The first active trench ACT1 and the third active trench ACT3 may expose the first lateral surface S1 and the third lateral surface S3 of the second active cutting pattern ACP2.

Referring still to FIGS. 17F, 17G, and 17H, the wet etching process may form the second cutting pattern CP2. The second cutting pattern CP2 may refer to a residual of the preliminary cutting pattern PCP that remains after the wet etching process. The second cutting pattern CP2 may cover the lateral surface and the bottom surface of the first cutting pattern CP1. The second cutting pattern CP2 may expose a portion of the lateral surface of the first cutting pattern CP1.

The second cutting pattern CP2 may include a first cutting portion P1 that covers the bottom surface and the lateral surface of the first cutting pattern CP1. The first cutting portion P1 may cover the bottom surface of the first cutting pattern CP1, and may also cover lower portions of the first, second, third, and fourth lateral surfaces S1, S2, S3, and S4 of the first cutting pattern CP1. A top surface P1_U of the first cutting portion P1 may be exposed by each of the active trenches ACT. The top surface P1_U of the first cutting portion P1 may be located at a level lower than that of a top surface CP1_U of the first cutting pattern CP1. A bottom surface P1_L of the first cutting portion P1 may be located at a level lower than that of a bottom surface CP1_L of the first cutting pattern CP1. The bottom surface P1_L of the first cutting portion P1 may be referred to as a bottom surface of the second cutting pattern CP2.

The second cutting pattern CP2 may include second cutting portions P2 that extend in the third direction D3 from the first cutting portion P1. The second cutting portions P2 may extend onto upper portions of the second and fourth lateral surfaces S2 and S4 of the first cutting pattern CP1. The second cutting portions P2 may be spaced apart from each other in the second direction D2. A first distance P2_D1 in the second direction D2 between the second cutting portions P2 may be greater than a width ACT_W in the second direction D2 of each of the active trenches ACT. The second cutting portions P2 may partially cover the second lateral surface S2 and the fourth lateral surface S4 of the first cutting pattern CP1. Each of uppermost surfaces P2_U of the second cutting portions P2 may be coplanar with the top surface CP1_U of the first cutting pattern CP1. Each of uppermost surfaces P2_U of the second cutting portions P2 may be located at a level higher than that of the top surface P1_U of the first cutting portion P1.

Referring back to FIGS. 4 to 5G, active contacts AC may formed to fill the active trenches ACT. A first active contact AC1 may fill the first active trench ACT1. The first active contact AC1 may contact the first lateral surface S1 of the first active cutting pattern ACP1, and may also contact the third lateral surface S3 of the second active cutting pattern ACP2.

A second active contact AC2 may fill the second active trench ACT2. The second active contact AC2 may contact the third lateral surface S3 of the first active cutting pattern ACP1.

A third active contact AC3 may fill the third active trench ACT3. The third active contact AC3 may contact the first lateral surface S1 of the second active cutting pattern ACP2.

According to one or more embodiments, after the removal of the exposed preliminary cutting pattern PCP, the active contacts AC may be formed. Thus, each of the active contacts AC may have an increased area. Thus, a semiconductor device with improved electrical properties may be provided.

A gate contact GC may be formed to penetrate the second interlayer dielectric layer 120 and the gate capping pattern GP to come into electrical connection with the gate electrode GE.

The formation of the gate contact GC and each of the active contacts AC may include forming a barrier pattern BM and forming a conductive pattern FM on the barrier pattern BM. The barrier pattern BM may be conformally formed, and may include a metal layer and a metal nitride layer. The conductive pattern FM may include metal with a resistance that is low.

Separation structures DB may be formed. The separation structure DB may extend from the second interlayer dielectric layer 120 through the gate electrode GE into the active pattern AP1 or AP2. The separation structure DB may include a dielectric material, such as a silicon oxide layer or a silicon nitride layer.

A third interlayer dielectric layer 130 may be formed on the active contacts AC and the gate contacts GC. A first metal layer M1 may be formed in the third interlayer dielectric layer 130. A fourth interlayer dielectric layer 140 may be formed on the third interlayer dielectric layer 130. A second metal layer M2 may be formed in the fourth interlayer dielectric layer 140.

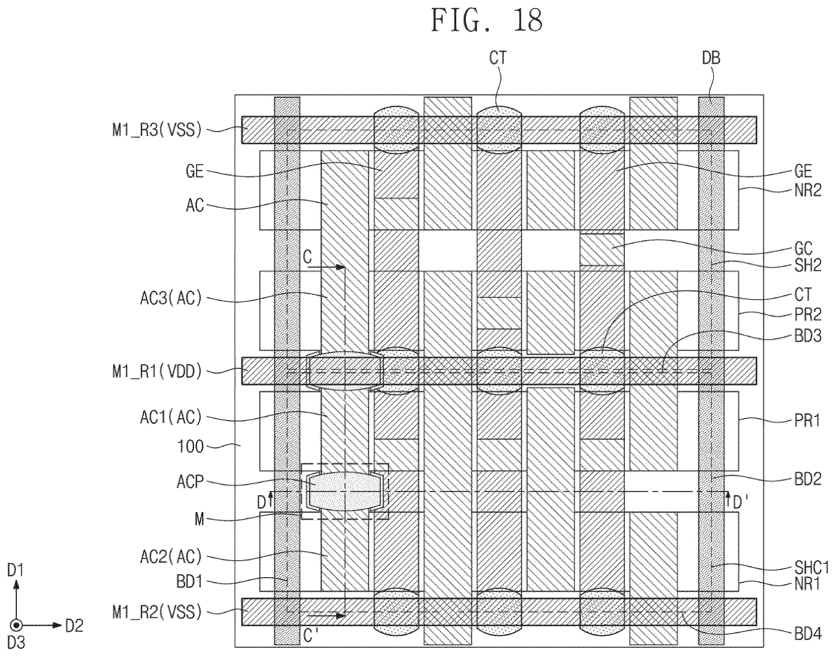

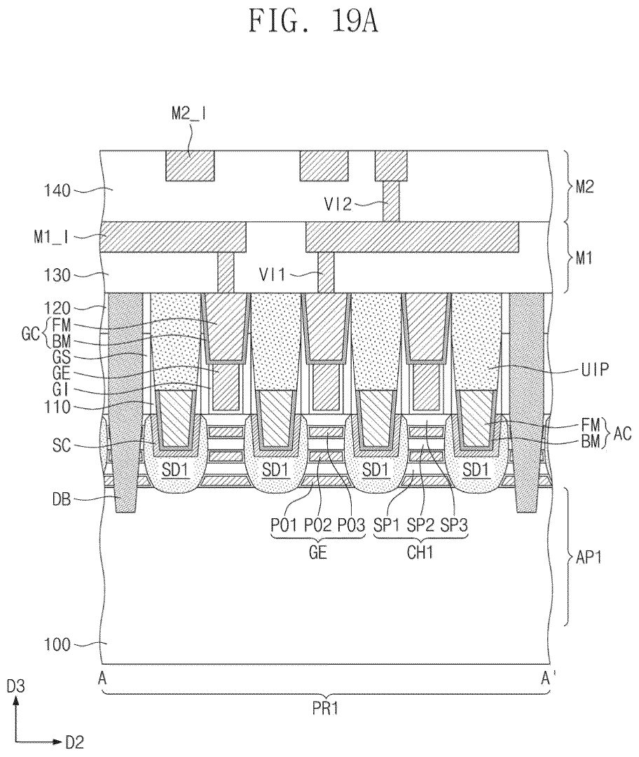

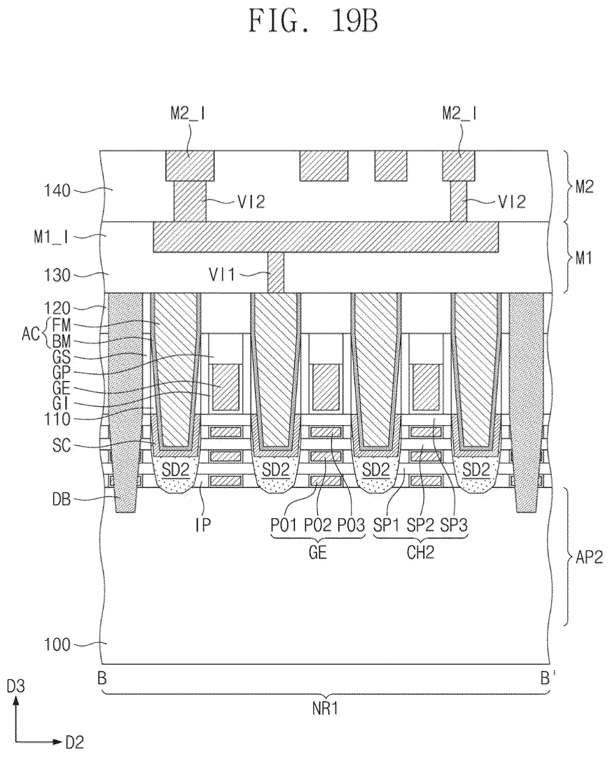

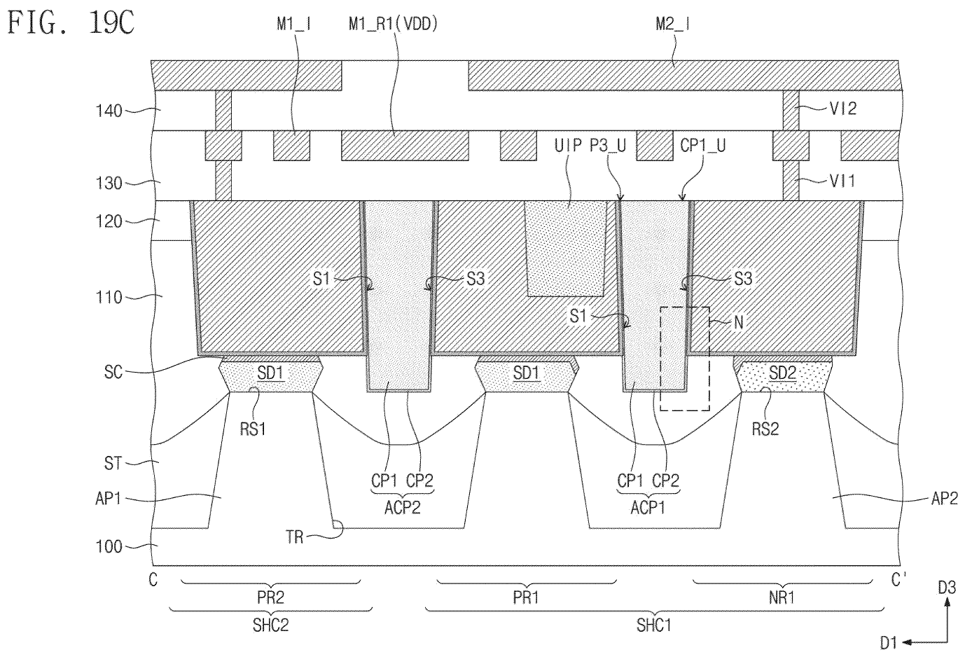

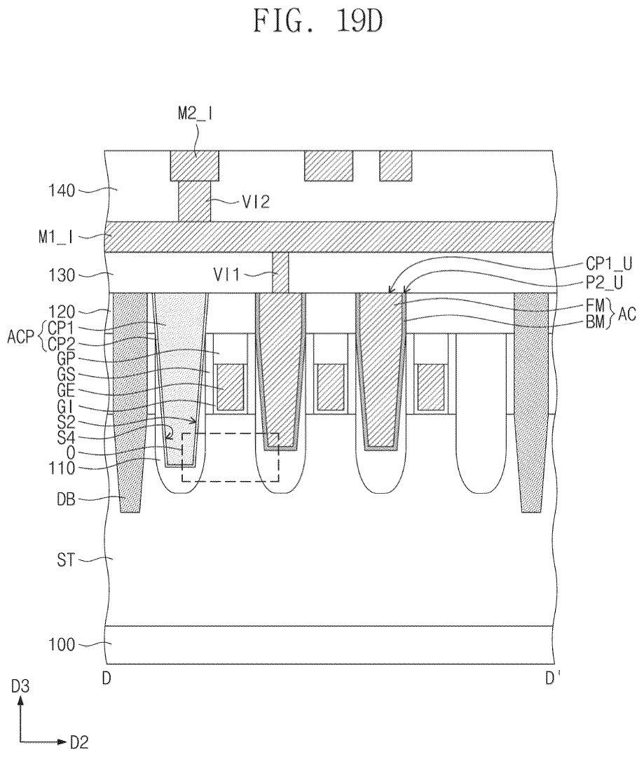

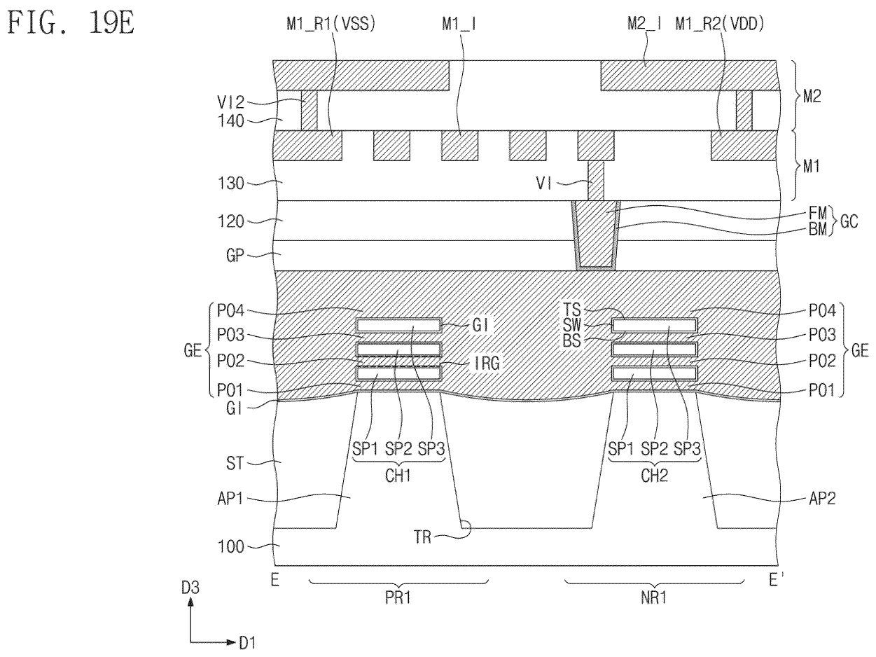

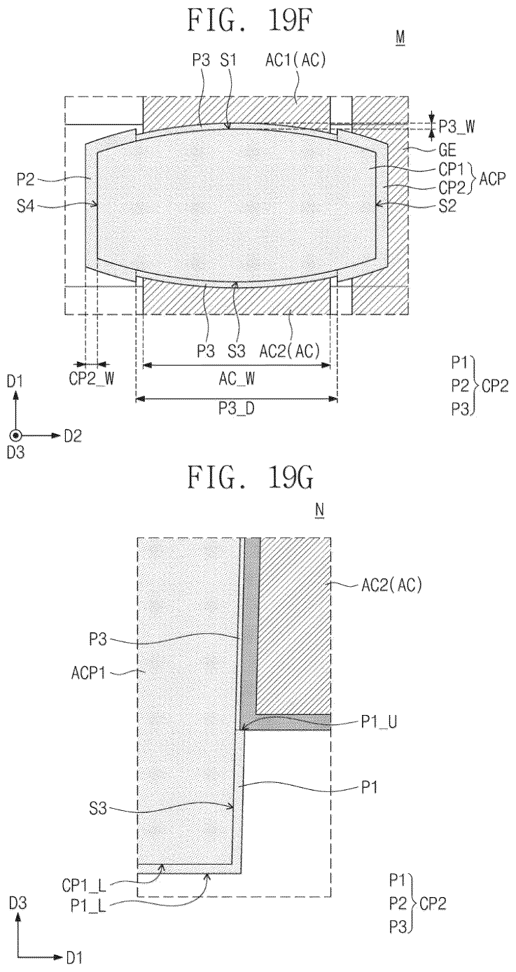

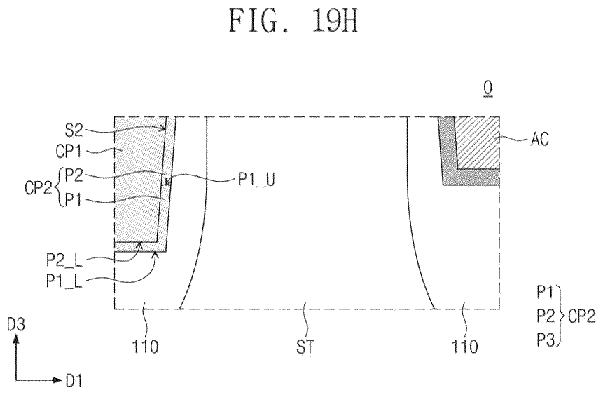

FIG. 18 is a plan view illustrating a semiconductor device according to one or more embodiments. FIGS. 19A to 19E are cross-sectional views illustrating a semiconductor device according to one or more embodiments. FIG. 19F is an enlarged view illustrating section M of FIG. 18 according to one or more embodiments. FIG. 19G is an enlarged view illustrating section N of FIG. 19C according to one or more embodiments. FIG. 19H is an enlarged view illustrating section O of FIG. 19D according to one or more embodiments. Description of aspects that are the same as or similar to those described above may be omitted.

Referring to FIGS. 18 and 19A to 19E, active cutting patterns ACP may be disposed between the active contacts AC. For example, a first active cutting pattern ACP1 may be disposed between the first active contact AC1 and the second active contact AC2. A second active cutting pattern ACP2 may be disposed between the first active contact AC1 and the third active contact AC3.

At least a portion of each of the active cutting patterns ACP may overlap the gate electrode GE in a vertical direction. The active cutting patterns ACP may include a dielectric material. The first active cutting pattern ACP1 may electrically insulate the first active contact AC1 and the second active contact AC2 from each other. The second active cutting pattern ACP2 may electrically insulate the first active contact AC1 and the third active contact AC3 from each other. A lowermost surface of each of the active cutting patterns ACP may be located at a level lower than that of a lowermost surface of each of the active contacts AC.

Referring further to FIGS. 19G and 19H, each of the active cutting patterns ACP may include a first cutting pattern CP1 that extends towards the substrate 100 and a second cutting pattern CP2 on a lateral surface and a bottom surface of the first cutting pattern CP1.

The first cutting pattern CP1 may have a first lateral surface S1 and a third lateral surface S3 that are opposite to each other. The first lateral surface S1 and the third lateral surface S3 may face the active contacts AC. The first lateral surface S1 and the third lateral surface S3 may be opposite to each other in the first direction D1.

The first cutting pattern CP1 may have a second lateral surface S2 across from the first lateral surface S1, and may also have a fourth lateral surface S4 opposite to the second lateral surface S2. The second lateral surface S2 and the fourth lateral surface S4 may be spaced apart from each other in the second direction D2.

The first cutting pattern CP1 and the second cutting pattern CP2 may include different materials from each other. A dielectric constant of the first cutting pattern CP1 may be greater than that of the second cutting pattern CP2. The first cutting pattern CP1 may include silicon nitride, for example, SiN.

The second cutting pattern CP2 may surround the lateral surface and the bottom surface of the first cutting pattern CP1. The second cutting pattern CP2 may include silicon oxycarbide, for example, SiOC.

The second cutting pattern CP2 may include a first cutting portion P1 that covers the bottom surface and the lateral surface of the first cutting pattern CP1. The first cutting portion P1 may cover lower portions of the first, second, third, and fourth lateral surfaces S1, S2, S3, and S4 of the first cutting pattern CP1. The top surface P1_U of the first cutting portion P1 may be located at a level lower than that of a top surface CP1_U of the first cutting pattern CP1. A bottom surface P1_L of the first cutting portion P1 may be located at a level lower than that of a bottom surface CP1_L of the first cutting pattern CP1. The bottom surface P1_L of the first cutting portion P1 may be referred to as a bottom surface of the second cutting pattern CP2, and may also be referred to as a lowermost surface of each of the active cutting patterns ACP.

The second cutting pattern CP2 may include second cutting portions P2 that extend in the third direction D3 from the first cutting portion P1. The second cutting portions P2 may extend onto upper portions of the second and fourth lateral surfaces S2 and S4 of the first cutting pattern CP1. Each of uppermost surfaces P2_U of the second cutting portions P2 may be coplanar with the top surface CP1_U of the first cutting pattern CP1. Each of uppermost surfaces P2_U of the second cutting portions P2 may be located at a level higher than that of the top surface P1_U of the first cutting portion P1.

The first cutting portion P1 and the second cutting portions P2 may include a first dielectric material including carbon. A carbon amount of the first cutting portion P1 may range from about 5 mol % to about 20 mol % relative to 100 mol % of the first dielectric material. A carbon amount of the second cutting portions P2 may range from about 5 mol % to about 20 mol % relative to 100 mol % of the first dielectric material.

The second cutting pattern CP2 may include third cutting portions P3 that extend in the third direction D3 from the first cutting portion P1. The third cutting portions P3 may extend onto upper portions of the first and third lateral surfaces S1 and S3 of the first cutting pattern CP1. A width P3_D in the second direction D2 of each of the third cutting portions P3 may be greater than a width AC_W in the second direction D2 of each of the active contacts AC.

A thickness P3_W of each of the third cutting portions P3 may be different from a thickness P2_W of each of the second cutting portions P2. The third thickness P3_W of each of the third cutting portions P3 may indicate a thickness measured in the first direction D1 on a lateral surface of the first cutting pattern CP1. The thickness P2_W of each of the second cutting portions P2 may indicate a thickness measured in the second direction D2 on the lateral surface of the first cutting pattern CP1. The thickness P3_W of each of the third cutting portions P3 may be less than the thickness P2_W of each of the second cutting portions P2. The thickness P3_W of each of the third cutting portions P3 may range, for example, from about 0.01 nm to about 0.1 nm. The thickness P2_W of each of the second cutting portions P2 may range, for example, from about 3 nm to about 5 nm.

The third cutting portions P3 may include a second dielectric material including carbon. A carbon amount of the third cutting portions P3 may be less than that of the first cutting portion P1. The carbon amount of the third cutting portions P3 may be less than that of the second cutting portions P2. The carbon amount of the third cutting portions P3 may range, for example, from about 0.01 mol % to about 3 mol % relative to 100 mol % of the second dielectric material.

The third cutting portions P3 may have an etch selectivity with respect to at least one selected from the first cutting portion P1, the second cutting portions P2, and the first cutting pattern CP1. As the third cutting portions P3 have their reduced carbon amount, the third cutting portions P3 may have an etch selectivity different from those of the first cutting portion P1, the second cutting portions P2, and the first cutting pattern CP1.

The third cutting portions P3 may contact the active contacts AC. For example, the third cutting portions P3 of the first active cutting pattern ACP1 may contact the first active contact AC1 and the second active contact AC2. The third cutting portions P3 of the second active cutting pattern ACP2 may contact the third active contact AC3 and the first active contact AC1.

Each of uppermost surfaces P3_U of the third cutting portions P3 may be coplanar with the top surface P1_U of the first cutting portion P1. Each of uppermost surfaces P3_U of the third cutting portions P3 may be coplanar with the top surface CP1_U of the first cutting pattern CP1.

According to one or more embodiments, the third cutting portions P3 of the second cutting pattern CP2 may each have an extremely small thickness. Thus, the active cutting patterns ACP may each have a reduced size (e.g., a width in the first direction D1). Accordingly, as each of the active contacts AC has an increased area, a semiconductor device may improve in electrical properties.

In addition, the second cutting pattern CP2 may have a dielectric constant less than that of the first cutting pattern CP1. Thus, an improved capacitance may be provided between neighboring active contacts AC. Accordingly, a semiconductor device may improve in electrical properties.

Other configurations may be identical to those discussed with reference to FIGS. 4 to 5G.

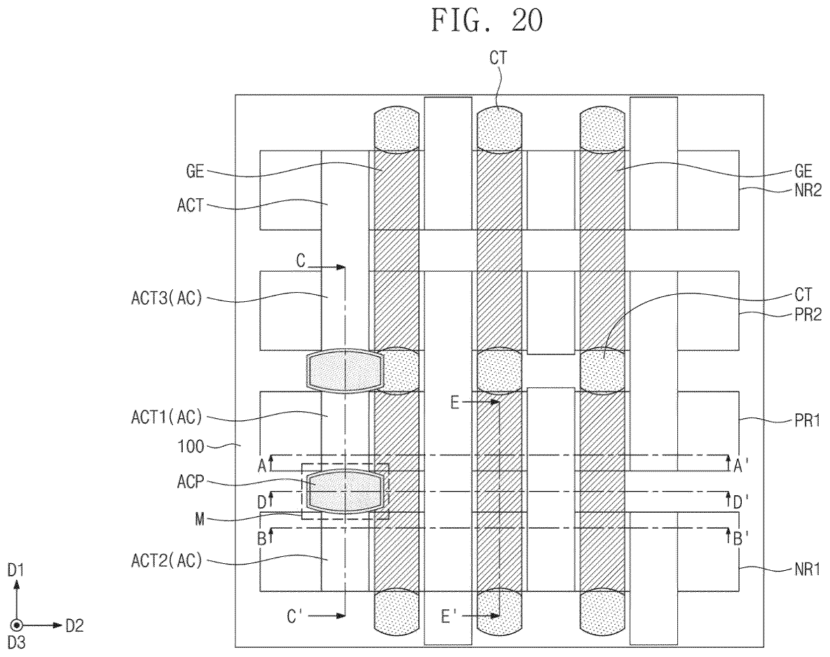

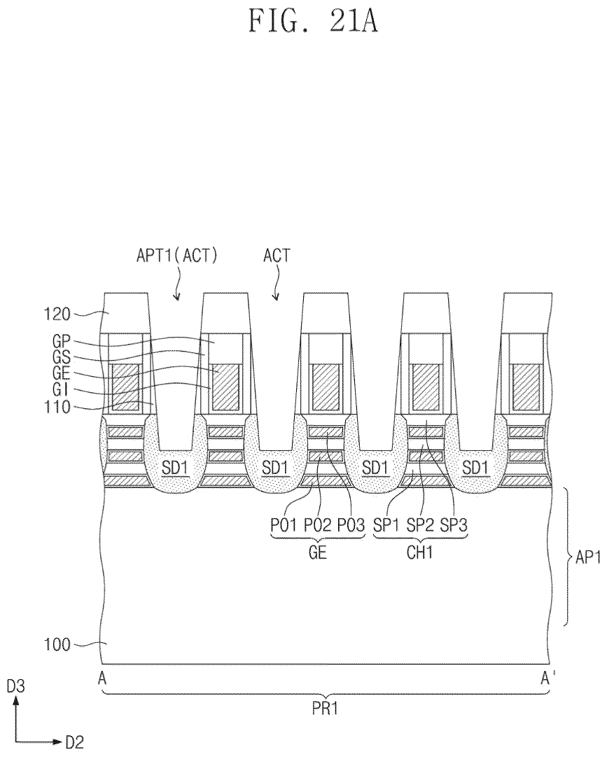

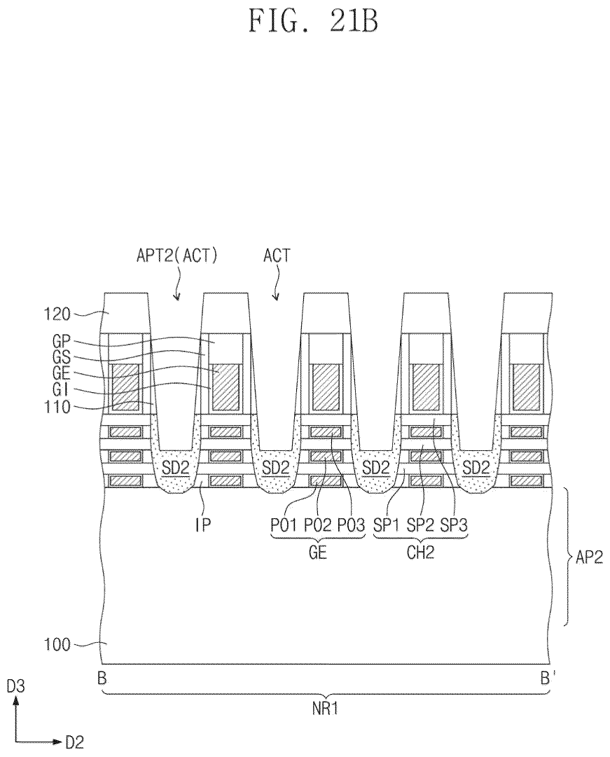

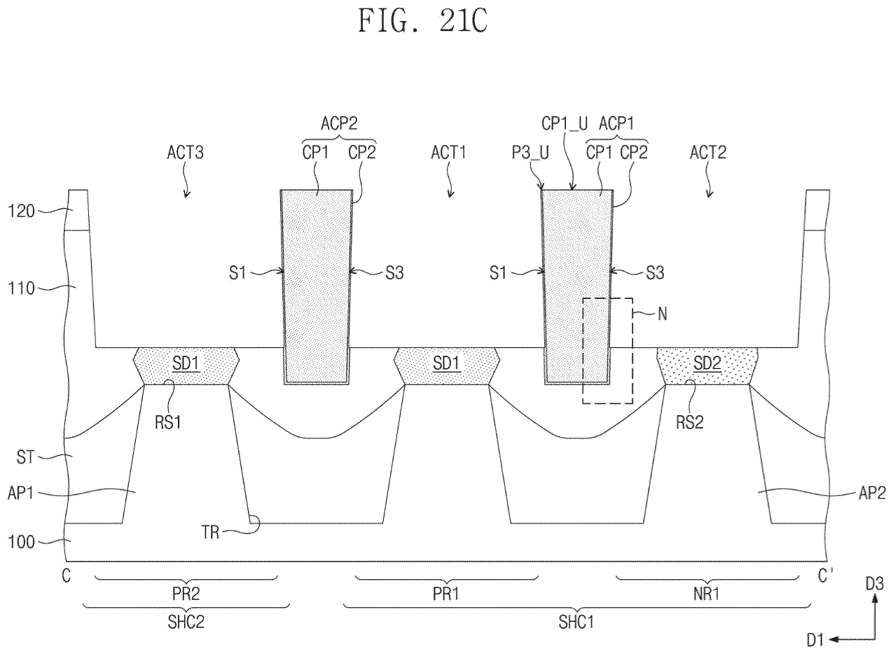

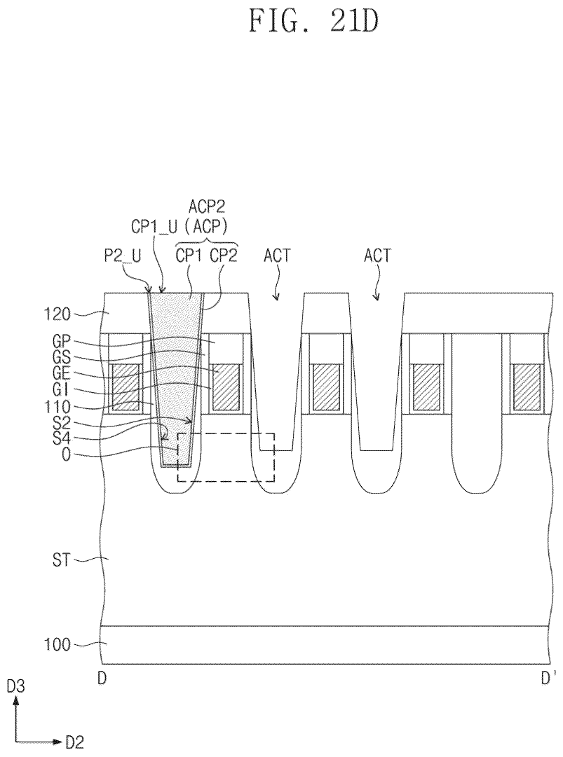

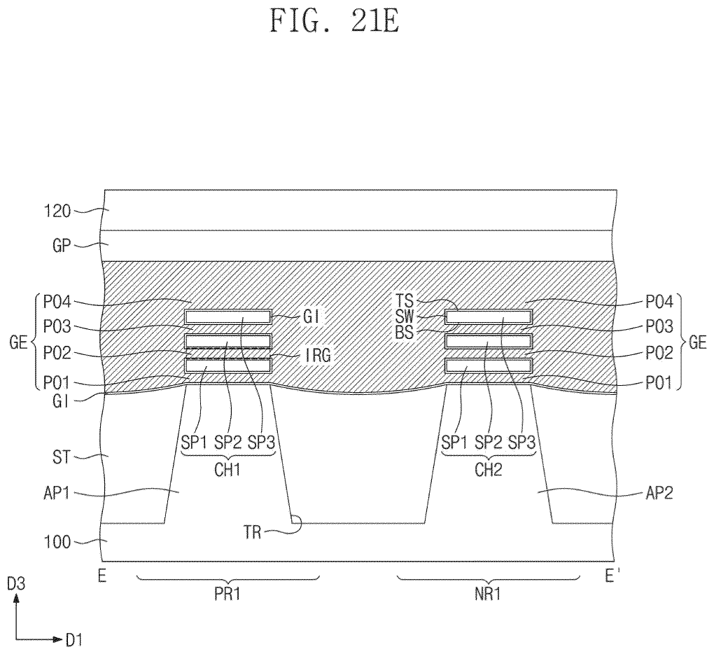

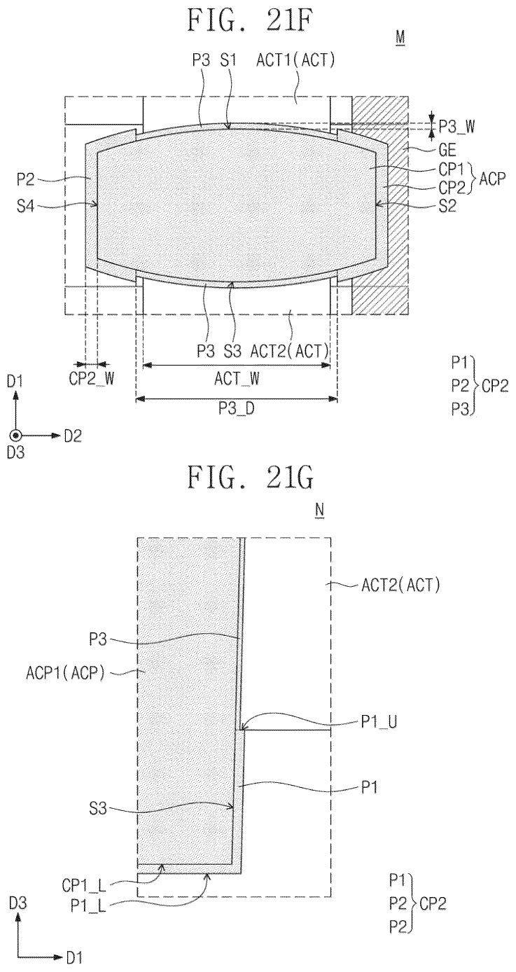

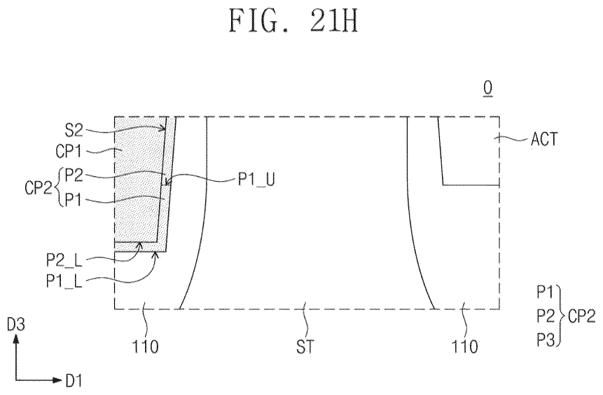

FIGS. 20 to 21H are diagrams illustrating a method of fabricating a semiconductor device according to one or more embodiments. FIG. 20 illustrates a plan view showing a semiconductor device according to one or more embodiments. FIG. 21A illustrates a cross-sectional view taken along line A-A′ of FIG. 20. FIG. 21B illustrates a cross-sectional view taken along line B-B′ of FIG. 20. FIG. 21C illustrates a cross-sectional view taken along line C-C′ of FIG. 20. FIG. 21D illustrates a cross-sectional view taken along line D-D′ of FIG. 20. FIG. 21E illustrates a cross-sectional view taken along line E-E′ of FIG. 20. FIG. 21F illustrates an enlarged view showing section M of FIG. 20. FIG. 21G illustrates an enlarged view showing section N of FIG. 21C. FIG. 21H illustrates an enlarged view showing section O of FIG. 21D. Description of aspects that are the same as or similar to those described above may be omitted.

Referring back to FIGS. 11A to 11E, cutting trenches APT may be formed to penetrate the second interlayer dielectric layer 120 and the first interlayer dielectric layer 110. A first cutting trench APT1 may be formed between the first source/drain pattern SD1 of the first PMOSFET region PR1 and the second source/drain pattern SD2 of the first NMOSFET region NR1. A second cutting trench APT2 may be formed between the first source/drain pattern SD1 of the first PMOSFET region PR1 and the first source/drain pattern SD1 of the second PMOSFET region PR2.

Referring back to FIGS. 12 and 13A to 13F, active cutting patterns ACP may fill the cutting trenches APT. At least a portion of each of the active cutting patterns ACP may vertically overlap the gate electrode GE.

A first active cutting pattern ACP1 may be formed between the first source/drain pattern SD1 of the first PMOSFET region PR1 and the second source/drain pattern SD2 of the first NMOSFET region NR1. A second active cutting pattern ACP2 may be formed between the first source/drain pattern SD1 of the first PMOSFET region PR1 and the first source/drain pattern SD1 of the second PMOSFET region PR2.

Each of the active cutting patterns ACP may include a first cutting pattern CP1 and a preliminary cutting pattern PCP that covers a lateral surface and a bottom surface of the first cutting pattern CP1. The first cutting pattern CP1 and the preliminary cutting pattern PCP may include different materials from each other. A dielectric constant of the first cutting pattern CP1 may be greater than that of the preliminary cutting pattern PCP. The first cutting pattern CP1 may include silicon nitride, for example, SiN. An amount of carbon in the preliminary cutting pattern PCP may range from about 5 mol % to about 20 mol % relative to 100 mol % of the dielectric material. The preliminary cutting pattern PCP may include silicon oxycarbide, for example, SiOC.

The first cutting pattern CP1 may have a first lateral surface S1 and a third lateral surface S3 that are opposite to each other. The first lateral surface S1 and the third lateral surface S3 may face the first and second source/drain patterns SD1 and SD2. The first lateral surface S1 and the third lateral surface S3 may be opposite to each other in the first direction D1.

For example, the first lateral surface S1 of the first active cutting pattern ACP1 may face the first source/drain pattern SD1 of the first PMOSFET region PR1. The third lateral surface S3 of the first active cutting pattern ACP1 may face the second source/drain pattern SD2 of the first NMOSFET region NR1.

The first lateral surface S1 of the second active cutting pattern ACP2 may face the first source/drain pattern SD1 of the second PMOSFET region PR2. The third lateral surface S3 of the second active cutting pattern ACP2 may face the first source/drain pattern SD1 of the first PMOSFET region PR1.

The first cutting pattern CP1 may have a second lateral surface S2 across from the first lateral surface S1, and may also have a fourth lateral surface S4 opposite to the second lateral surface S2. The second lateral surface S2 and the fourth lateral surface S4 may be opposite to each other in the second direction D2.

The preliminary cutting pattern PCP may cover the lateral surface and the bottom surface of the first cutting pattern CP1. The preliminary cutting pattern PCP may cover all of the first, second, third, and fourth lateral surfaces S1, S2, S3, and S4 of the first cutting pattern CP1. A thickness PCP_W of the preliminary cutting pattern PCP may range, for example, from about 3 nm to about 5 nm.

Referring back to FIGS. 14 and 15A to 15E, active trenches ACT may be formed to penetrate the second interlayer dielectric layer 120 and the first interlayer dielectric layer 110.

A first active trench ACT1 may be formed on the first source/drain pattern SD1 of the first PMOSFET region PR1. The first active trench ACT1 may expose a top surface of the first source/drain pattern SD1. A second active trench ACT2 may be formed on the second source/drain pattern SD2 of the first NMOSFET region NR1. The second active trench ACT2 may expose a top surface of the second source/drain pattern SD2. A third active trench ACT3 may be formed on the first source/drain pattern SD1 of the second PMOSFET region PR2. The third active trench ACT3 may expose a top surface of the first source/drain pattern SD1.

Referring to FIGS. 15C, 15D, and 15F, the first active cutting pattern ACP1 may be interposed between the first active trench ACT1 and the second active trench ACT2. The first active trench ACT1 and the second active trench ACT2 may expose a lateral surface of the first active cutting pattern ACP1. The preliminary cutting pattern PCP may be exposed which is provided on the first lateral surface S1 and the third lateral surface S3 of the first active cutting pattern ACP1.

The second active cutting pattern ACP2 may be interposed between the first active trench ACT1 and the third active trench ACT3. The first active trench ACT1 and the third active trench ACT3 may expose a lateral surface of the second active cutting pattern ACP2. The preliminary cutting pattern PCP may be exposed which is provided on the first lateral surface S1 and the third lateral surface S3 of the second active cutting pattern ACP2.

According to one or more embodiments, each of the first active cutting pattern ACP1 and the second active cutting pattern ACP2 may include the preliminary cutting pattern PCP. Thus, a reduced distance may be provided between the first active cutting pattern ACP1 and the second active cutting pattern ACP2.

The distance may be decreased to reduce failure where the top surfaces of the first and second source/drain patterns SD1 and SD2 are not exposed. Accordingly, a method of fabricating a semiconductor device with improved reliability may be provided.

Referring to FIGS. 20 and 21A to 21E, an ashing process and a wet etching process may be performed to remove impurities. The ashing process and the wet etching process may remove impurities produced in an etching process for forming the active trenches ACT.

The ashing process and the wet etching process may remove a portion of the exposed preliminary cutting pattern PCP. The ashing process may cause a reduction in carbon amount of the exposed preliminary cutting pattern PCP.

For example, the preliminary cutting pattern PCP may include a dielectric material including carbon. A carbon amount of the preliminary cutting pattern PCP may range from about 5 mol % to about 20 mol % relative to 100 mol % of the dielectric material.

The ashing process may allow the exposed preliminary cutting pattern PCP to have a reduced carbon amount. A carbon amount of the preliminary cutting pattern PCP may range from about 0.01 mol % to about 3 mol % relative to 100 mol % of the dielectric material.

Therefore, the exposed preliminary cutting pattern PCP and the preliminary cutting pattern PCP may have different etch selectivity from each other. In the wet etching process, the exposed preliminary cutting pattern PCP may be partially etched, but the preliminary cutting pattern PCP may not be etched.

Referring still to FIGS. 21F to 21H, the wet etching process may form the second cutting pattern CP2. The second cutting pattern CP2 may refer to a residual of the preliminary cutting pattern PCP that remains after the wet etching process. The second cutting pattern CP2 may cover the lateral surface and the bottom surface of the first cutting pattern CP1. The second cutting pattern CP2 may include silicon oxycarbide, for example, SiOC.

The second cutting pattern CP2 may include a first cutting portion P1 that covers the bottom surface and the lateral surface of the first cutting pattern CP1. The first cutting portion P1 may cover the bottom surface of the first cutting pattern CP1, and may also cover lower portions of the first, second, third, and fourth lateral surfaces S1, S2, S3, and S4 of the first cutting pattern CP1. The top surface P1_U of the first cutting portion P1 may be located at a level lower than that of a top surface CP1_U of the first cutting pattern CP1. A bottom surface P1_L of the first cutting portion P1 may be located at a level lower than that of a bottom surface CP1_L of the first cutting pattern CP1.

The second cutting pattern CP2 may include second cutting portions P2 that extend in the third direction D3 from the first cutting portion P1. The second cutting portions P2 may extend onto upper portions of the second and fourth lateral surfaces S2 and S4 of the first cutting pattern CP1. Each of uppermost surfaces P2_U of the second cutting portions P2 may be coplanar with the top surface CP1_U of the first cutting pattern CP1. Each of uppermost surfaces P2_U of the second cutting portions P2 may be located at a level higher than that of the top surface P1_U of the first cutting portion P1.

The first cutting portion P1 and the second cutting portions P2 may include a first dielectric material including carbon. A carbon amount of the first cutting portion P1 may range from about 5 mol % to about 20 mol % relative to 100 mol % of the first dielectric material. A carbon amount of the second cutting portions P2 may range from about 5 mol % to about 20 mol % relative to 100 mol % of the first dielectric material.

The second cutting pattern CP2 may include third cutting portions P3 that extend in the third direction D3 from the first cutting portion P1. The third cutting portions P3 may extend onto upper portions of the first and third lateral surfaces S1 and S3 of the first cutting pattern CP1. A width P3_D in the second direction D2 of each of the third cutting portions P3 may be greater than a width ACT_W in the second direction D2 of each of the active trenches ACT.

A thickness P3_W of each of the third cutting portions P3 may be different from a thickness P2_W of each of the second cutting portions P2. The thickness P3_W of each of the third cutting portions P3 may be measured in the first direction D1 on a lateral surface of the first cutting pattern CP1. The thickness P2_W of each of the second cutting portions P2 may be measured in the second direction D2 on the lateral surface of the first cutting pattern CP1.

The thickness P3_W of each of the third cutting portions P3 may be less than the thickness P2_W of each of the second cutting portions P2. The thickness P3_W of each of the third cutting portions P3 may range, for example, from about 0.01 nm to about 0.1 nm. The thickness P2_W of each of the second cutting portions P2 may range, for example, from about 3 nm to about 5 nm.

Each of uppermost surfaces P3_U of the third cutting portions P3 may be coplanar with the top surface P1_U of the first cutting portion P1. Each of uppermost surfaces P3_U of the third cutting portions P3 may be coplanar with the top surface CP1_U of the first cutting pattern CP1.

According to one or more embodiments, the third cutting portions P3 of the second cutting pattern CP2 may each have an extremely small thickness. Thus, the active cutting pattern ACP may have a reduced size (e.g., a width in the first direction D1). Accordingly, the active contacts AC may each have an increased area, and thus a semiconductor device may improve in electrical properties.

In addition, the second cutting pattern CP2 may have a dielectric constant less than that of the first cutting pattern CP1. Thus, an improved capacitance may be provided between neighboring active contacts AC. Accordingly, a semiconductor device may improve in electrical properties.

Except that discussed above, a method of fabricating a semiconductor device may be identical to the method of fabricating a semiconductor device discussed with reference to FIGS. 6A to 17H.

A semiconductor device according to some embodiments of the present inventive concepts may include a cutting pattern including a first cutting pattern and a second cutting pattern. The second cutting pattern may be partially removed during fabrication of an active contact. Therefore, the active contact may have an increased area, and thus the semiconductor device may improve in electrical properties.

In addition, the second cutting pattern may include a material whose dielectric constant is low. Therefore, an improved capacitance may be provided between neighboring active patterns. Accordingly, the semiconductor device may improve in electrical properties.

Additionally, the second cutting pattern may be formed to have an increased thickness. Hence, a reduced distance may be provided between neighboring cutting patterns. As even a source/drain pattern can be sufficiently etched in an etching process for manufacturing the active contact, it may be possible to provide a method of fabricating a semiconductor device with improved reliability.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is

1. A semiconductor device, comprising:
a substrate comprising a first active pattern and a second active pattern that are spaced apart from each other in a first direction that is parallel to a top surface of the substrate;
a first source/drain pattern on the first active pattern;
a second source/drain pattern on the second active pattern;
a first active contact on the first source/drain pattern;
a second active contact on the second source/drain pattern; and
a cutting pattern between the first active contact and the second active contact,
wherein the cutting pattern comprises:
a first cutting pattern between the first active contact and the second active contact, the first cutting pattern extending toward the substrate; and
a second cutting pattern on at least one lateral surface of the first cutting pattern and a bottom surface of the first cutting pattern, the second cutting pattern exposing at least a portion of the at least one lateral surface of the first cutting pattern.

2. The semiconductor device of claim 1, wherein the first cutting pattern comprises a material that is different from a material of the second cutting pattern.

3. The semiconductor device of claim 1, wherein a dielectric constant of the second cutting pattern is less than a dielectric constant of the first cutting pattern.

4. The semiconductor device of claim 1, wherein the first cutting pattern comprises silicon nitride, and
wherein the second cutting pattern comprises silicon oxycarbide.

5. The semiconductor device of claim 1, further comprising:
a first channel pattern on the first active pattern;
a second channel pattern on the second active pattern; and
a gate electrode across the first channel pattern and the second channel pattern,
wherein at least a portion of the second cutting pattern overlaps the gate electrode in a second direction that is perpendicular to the top surface of the substrate.

6. The semiconductor device of claim 1, wherein a first lateral surface of the first cutting pattern contacts the first active contact, the first lateral surface of the first cutting pattern being exposed by the second cutting pattern.

7. The semiconductor device of claim 1, wherein a thickness of the second cutting pattern is 3 nm to 5 nm.

8. The semiconductor device of claim 1, wherein a bottom surface of the second cutting pattern is at a level that is lower than a level of the bottom surface of the first cutting pattern.

9. The semiconductor device of claim 1, wherein the first cutting pattern has a first lateral surface and a second lateral surface that are opposite to each other in a second direction that is parallel to the top surface of the substrate and intersects the first direction,
wherein the second cutting pattern comprises a plurality of first cutting portions that are spaced apart from each other in the second direction, and
wherein the plurality of first cutting portions at least partially cover the first lateral surface of the first cutting pattern and the second lateral surface of the first cutting pattern.

10. The semiconductor device of claim 9, wherein the plurality of first cutting portions are spaced from each other by a first distance in the second direction, and
wherein the first distance in the second direction between the plurality of first cutting portions is greater than a width of the first active contact in the second direction.

11. A semiconductor device, comprising:
a substrate comprising a first active pattern and a second active pattern;
a first source/drain pattern on the first active pattern;
a second source/drain pattern on the second active pattern;
a first active contact on the first source/drain pattern;
a second active contact on the second source/drain pattern; and
a cutting pattern between the first active contact and the second active contact,
wherein the cutting pattern comprises:
a first cutting pattern between the first active contact and the second active contact, the first cutting pattern extending toward the substrate; and
a second cutting pattern on at least one lateral surface of the first cutting pattern and a bottom surface of the first cutting pattern,
wherein the first cutting pattern comprises:
a first lateral surface that faces the first active contact; and
a second lateral surface across from the first lateral surface,
wherein the second cutting pattern comprises:
a first cutting portion on the first lateral surface of the first cutting pattern, the first cutting portion having a first thickness; and
a second cutting portion on the second lateral surface of the first cutting pattern, the second cutting portion having a second thickness,
wherein the first thickness is different from the second thickness.

12. The semiconductor device of claim 11, wherein the first thickness of the first cutting portion is less than the second thickness of the second cutting portion.

13. The semiconductor device of claim 11, wherein the second thickness of the second cutting portion is 3 nm to 5 nm.

14. The semiconductor device of claim 11, wherein the first cutting portion comprises a first dielectric material comprising carbon,
wherein the second cutting portion comprises a second dielectric material comprising carbon, and
wherein a carbon amount of the first cutting portion is less than a carbon amount of the second cutting portion.

15. The semiconductor device of claim 14, wherein the carbon amount of the first cutting portion is about 0.01 mol % to about 3 mol % relative to 100 mol % of the first dielectric material, and
wherein the carbon amount of the second cutting portion is about 5 mol % to about 20 mol % relative to 100 mol % of the second dielectric material.

16. The semiconductor device of claim 11, wherein the first cutting pattern has an etch selectivity that is different from an etch selectivity of the first cutting portion of the second cutting pattern.

17. The semiconductor device of claim 11, wherein the first cutting pattern comprises a material that is different from a material of the second cutting pattern.

18. The semiconductor device of claim 11, wherein the first cutting portion contacts the first active contact.

19. A semiconductor device, comprising:
a substrate comprising a first active pattern and a second active pattern;
a device isolation layer between the first active pattern and the second active pattern;
a first source/drain pattern on the first active pattern;
a first channel pattern on the first active pattern;
a second source/drain pattern on the second active pattern;
a second channel pattern on the second active pattern;
a gate electrode across the first channel pattern and the second channel pattern;
a first active contact on the first source/drain pattern;
a second active contact on the second source/drain pattern; and
a cutting pattern between the first active contact and the second active contact,
wherein the cutting pattern comprises:
a first cutting pattern between the first active contact and the second active contact, the first cutting pattern extending toward the substrate; and
a second cutting pattern on at least one lateral surface of the first cutting pattern and a bottom surface of the first cutting pattern, the second cutting pattern exposing at least a portion of the at least one lateral surface of the first cutting pattern.

20. The semiconductor device of claim 19, wherein the first cutting pattern comprises silicon nitride, and
wherein the second cutting pattern comprises silicon oxycarbide.
